(19) United States
(12) Patent Application Publication
(10) Pub. No.: US 2022/0147664 A1
(43) Pub. Date: May 12, 2022

(54) Systems and Methods for Multi-Modal Transportation Simulation Verification

(71) Applicant: Joby Aero, Inc., Santa Cruz, CA (US)

(72) Inventors: Ian Andreas Villa, San Francisco, CA (US); Ryan Patrick Naru, Oakland, CA (US)

(21) Appl. No.: 17/523,961

(22) Filed: Nov. 11, 2021

Related U.S. Application Data
(60) Provisional application No. 63/112,276, filed on Nov. 11, 2020.

(51) Int. Cl. G06F 30/20

(52) U.S. Cl. CPC G06F 30/20

(57) ABSTRACT

Systems and methods for multi-modal transportation simulation verification are provided. A system includes a simulation system configured to generate simulation data, a planning system configured to determine a multi-modal transportation itinerary based on the simulation data, and a verification system configured to recommend modifications to the generation or selection of a multi-modal transportation itinerary. The verification system can obtain the simulation data and operational data indicative of a performed flight itinerary. The performed flight itinerary can correspond to a simulated flight itinerary of the simulation data. The system can determine performance deviations between the performed flight itinerary and the simulated flight itinerary. The system can generate corrective actions based on the performance deviations and provide the corrective actions to a respective system responsible for the performance deviation. The respective system can implement the corrective action by modifying a model, service, or function associated with the performance deviation.

### RELATED APPLICATIONS

This application claims priority to and the benefit of U.S. Provisional Patent Application No. 63/112,276, filed Nov. 11, 2020, which is hereby incorporated by reference in its entirety.

### FIELD

The present disclosure relates generally to facilitating multi-modal transportation services for riders. More particularly, the present disclosure relates to systems and methods for verification of multi-modal transportation systems via simulations.

### BACKGROUND

A wide variety of modes of transport are available within cities. For example, people can walk, ride a bike, drive a car, take public transit, or use a ride sharing service. As population densities and demand for land increase, however, many cities are experiencing problems with traffic congestion and the associated pollution. Consequently, there is a need to expand the available modes of transport in ways that can reduce the amount of traffic without requiring the use of large amounts of land.

Air travel within cities can reduce travel time over purely ground-based approaches and alleviate problems associated with traffic congestion. Vertical takeoff and landing (VTOL) aircraft provide opportunities to incorporate aerial transportation into transport networks for cities and metropolitan areas. VTOL aircraft require much less space to take-off and land than other types of aircraft, making them more suitable for densely populated urban environments.

### SUMMARY

Aspects and advantages of embodiments of the present disclosure will be set forth in part in the following description, or can be learned from the description, or can be learned through practice of the embodiments.

An example aspect of the present disclosure is directed to a computing system. The computing system includes one or more processors and one or more tangible, non-transitory, computer readable media that collectively store instructions that when executed by the one or more processors cause the computing system to perform operations. The operations include obtaining simulation data indicative of a simulated flight itinerary. The simulated flight itinerary is indicative of an expected performance of an aerial transportation service for a multi-modal transportation itinerary. The operations include obtaining operational data indicative of a performed flight itinerary of the multi-modal transportation itinerary. The performed flight itinerary is indicative of a recorded performance of the aerial transportation service. The operations include determining one or more performance deviations associated with the simulated flight itinerary based, at least in part, on the simulation data and the operational data. The operations include generating one or more corrective actions based, at least in part, on the one or more performance deviations. The one or more corrective actions are associated with at least one of a generation of the simulated flight itinerary or a selection of the simulated flight itinerary. And, the operations include outputting the one or more corrective actions.

Another example aspect of the present disclosure is directed to a computer-implemented method. The method includes obtaining, by a computing system including one or more computing devices, simulation data indicative of a simulated flight itinerary. The simulated flight itinerary is indicative of an expected performance of an aerial transportation service for a multi-modal transportation itinerary. The method includes obtaining, by the computing system, operational data indicative of a performed flight itinerary of the multi-modal transportation itinerary. The performed flight itinerary is indicative of a recorded performance of the aerial transportation service. The method includes determining, by the computing system, one or more performance deviations associated with the simulated flight itinerary based, at least in part, on the simulation data and the operational data. The method includes generating, by the computing system, one or more corrective actions based, at least in part, on the one or more performance deviations. The one or more corrective actions are associated with a selection of the simulated flight itinerary. And, the method includes outputting, by the computing system, the one or more corrective actions.

Yet another example aspect of the present disclosure is directed to one or more tangible, non-transitory computer-readable media storing computer-readable instructions that when executed by one or more processors cause the one or more processors to perform operations. The operations include obtaining simulation data indicative of a simulated flight itinerary. The simulated flight itinerary is indicative of an expected performance of an aerial transportation service. The operations include obtaining operational data indicative of a performed flight itinerary. The performed flight itinerary is indicative of a recorded performance of the aerial transportation service. The operations include determining one or more performance deviations associated with the simulated flight itinerary based, at least in part, on the recorded performance of the aerial transportation service. The operations include generating one or more corrective actions based, at least in part, on the one or more performance deviations. The one or more corrective actions are associated with at least one of a generation of the simulated flight itinerary or a selection of the simulated flight itinerary. And, the operations include providing the one or more corrective actions.

Other aspects of the present disclosure are directed to various systems, apparatuses, non-transitory computer-readable media, user interfaces, and electronic devices. These and other features, aspects, and advantages of various embodiments of the present disclosure will become better understood with reference to the following description and appended claims. The accompanying drawings, which are incorporated in and constitute a part of this specification, illustrate example embodiments of the present disclosure and, together with the description, serve to explain the related principles.

### BRIEF DESCRIPTION OF THE DRAWINGS

Detailed discussion of embodiments directed to one of ordinary skill in the art is set forth in the specification, which makes reference to the appended figures, in which:

FIG. 1 depicts a block diagram of an example computing system according to example embodiments of the present disclosure;

FIG. 2 depicts a graphical diagram of an example transportation node according to example embodiments of the present disclosure;

FIG. 3 depicts a graphical diagram of an example set of flight plans between an example set of transportation nodes according to example embodiments of the present disclosure;

FIG. 4 depicts an example vehicle provider ecosystem according to example embodiments of the present disclosure;

FIG. 5 depicts an example operational schedule according to example embodiments of the present disclosure;

FIG. 6 depicts a graphical diagram of an example multi-modal transportation service itinerary according to example embodiments of the present disclosure;

FIG. 7 depicts a data flow diagram for generating example operational constraints according to example embodiments of the present disclosure;

FIG. 8 depicts a data flow diagram for generating corrective actions according to example embodiments of the present disclosure;

FIG. 9 depicts a flow diagram of an example method for generating corrective actions according to example embodiments of the present disclosure;

FIG. 10 depicts another flow diagram of an example method for generating corrective actions according to example embodiments of the present disclosure;

FIG. 11 depicts a block diagram of an example computing system according to example embodiments of the present disclosure.

### DETAILED DESCRIPTION

Aspects of the present disclosure are directed to improved systems and methods for the generation and fulfillment of multi-modal transportation services. In particular, aspects of the present disclosure are directed to utilizing, verifying, and refining simulated multi-modal transportation services overtime to enhance systems involved in the generation and fulfillment of multi-modal transportation services in the real world. For instance, a service entity can manage and/or coordinate a plurality of different types of vehicles to provide services to a plurality of riders via a transportation platform. By way of example, rider can provide a service request for transportation from an origin location to a destination location. A service entity computing system associated with the service entity (e.g., a cloud-based operations computing, etc.) can receive data indicative of the service request and generate an itinerary to facilitate transporting the rider from the origin location to the destination location. The itinerary can be a multi-modal transportation itinerary for facilitating a multi-modal transportation service. The multi-modal transportation service can include at least two types of transportation services such as, for example, ground-based vehicle transportation services and/or aerial transportation services. For example, the itinerary can include three legs: a first leg that includes a ground-based vehicle transporting the rider from the origin location (e.g., a home, etc.) to a first aerial transport facility; a second leg (e.g., an aerial portion) that includes an aerial vehicle transporting the rider from the first aerial transport facility to a second aerial transport facility; and/or a third leg that includes another ground-based vehicle transporting the rider from the second aerial transport facility to the destination location (e.g., a conference center).

Transportation service(s) can be provided in accordance with the multi-modal transportation itinerary to facilitate the transportation of the rider from the origin location to the destination location. The transportation service(s) can be performed by vehicles of the service entity or vehicles provided by third-party vehicle providers associated with the service entity. For instance, the third-party vehicle provider(s) can include fleet(s) of aerial vehicles that can be assigned, operated, or otherwise provided to the service entity to perform aerial transportation service(s). As an example, the service entity can collaborate with a vehicle provider computing system to perform one or more transportation services (e.g., an aerial transportation service) in accordance with the multi-modal transportation itinerary.

The service entity computing system can leverage simulation data to optimize multi-modal transportation itineraries over an operational time period (e.g., hour(s), day(s), week(s), etc.). The simulation data can include a number of simulated transportation itineraries initiated and simulated based on a number of operational constraints representing the real world at one or more times throughout the operational time period. The service entity computing system can generate a number of simulated legs of multi-modal transportation itineraries (e.g., flight itineraries) for a current time step, generate a multi-modal transportation itinerary based on the simulated legs, and initiate the multi-modal transportation itinerary in the real-world. At times, one or more aspects of the simulated legs can deviate from one or more aspects of the performed itinerary. In order to generate better simulations, as well as, correct potential inaccuracies with one or more other systems involved in the generation and fulfillment of multi-modal transportation services, the service entity computing system can obtain operational data descriptive of a performed flight itinerary, determine performance deviations between the performed flight itinerary and a corresponding simulated flight itinerary, generate corrective actions to correct for the performance deviations, and output the corrective actions to one or more systems (e.g., a simulation system, a vehicle provider system, etc.) involved with the generation and fulfillment of multi-modal transportation itineraries. In this manner, the systems and methods of the present disclosure provide improved techniques for leveraging simulation data over time to generate corrective actions (e.g., model update, simulation parameter adjustment, etc.) specifically tailored to at least one of a number of systems involved in multi-modal transportation services.

More particularly, the service entity computing system and/or a vehicle provider computing system can operate (e.g., collectively or individually) to control, route, monitor, and/or communicate with aircraft (e.g., VTOL aircraft) and/or one or more other transportation service entities to facilitate a multi-modal transportation service. These operations can be performed as part of a multi-modal transportation service for riders, for example, including travel by ground vehicles and travel by aircraft (e.g., VTOL aircraft).

The service entity computing system can be communicatively connected over a network to the vehicle provider computing system, one or more rider devices, one or more service provider computing devices, and/or any other system or device involved in a multi-modal transportation service. The service entity computing system can include a number of different systems such as, for example, a world state system, forecasting system, optimization/planning system, matching and fulfillment system, simulation system, and/or verification system that can help plan and fulfill one or more portions of the multi-modal transportation service. Each system can provide one or more backend services of the service entity computing system to the one or more vehicle provider computing system(s) and/or other associated devices. For example, the world state system can provide a backend world state service, the forecasting system can provide a backend forecasting service, the optimization/planning system can provide a backend scheduling service, the matching and fulfillment system can provide an assignment service, the simulation system can provide a simulation service, and/or the verification system can provide a verification service.

By way of example, the world state system can operate a state monitoring service to maintain data descriptive of a current state of the world. The state monitoring service can generate, collect, and/or maintain data descriptive of planned itineraries; scheduled transportation plans (e.g., flight itineraries) and assignments; current service requests; current ground transportation service providers; current aerial transport facility operational statuses (e.g., including re-charging or re-fueling capabilities); current aerial vehicle statuses (e.g., including current fuel or battery level); current pilot statuses; current flight states and trajectories; current airspace information; current weather conditions; current communication system behavior/protocols; and/or the like. Such data can be obtained through communication (e.g., via an API platform) with one or more systems (e.g., vehicle provider computing systems) and/or devices (e.g., rider devices, etc.) associated with the service entity computing system.

The forecasting system can operate a forecasting service to generate predictions of transportation demand, weather forecasts, and/or any other future looking data helpful for completing a transportation service. As an example, the forecasting system can generate predictions of demand and supply for transportation services at or between various locations over time. The forecasting system can also generate or supply weather forecasts. The forecasts made by the system can be generated based on historical data and/or through modeling of supply and demand.

The optimization/planning system can operate a scheduling service to generate and/or obtain (e.g., from the vehicle provider computing system) transportation plans for various transportation assets. For example, the optimization/planning system can perform and/or facilitate route planning, flight planning, and/or multi-modal transportation planning. The matching and fulfillment system can operate an assignment service to match a rider with a service provider and/or a vehicle provider for each of the different transportation legs of a multi-modal transportation itinerary. For example, the assignment service can communicate trajectories and/or assignments to the corresponding service/vehicle providers.

The simulation system can operate a simulation service to generate and simulate, within a simulated world environment, a plurality of different multi-modal and/or flight itineraries at one or more different time steps throughout an operational time period. The optimization/planning system, the matching and fulfillment system, and/or the vehicle provider computing system can leverage the simulation data output by the simulation service to generate, schedule, assign, and/or fulfill a multi-modal transportation itinerary and/or one or more portions of a multi-modal transportation itinerary (e.g., an aerial transportation leg). As described herein, the verification system can operate a verification service that can obtain simulation and operational data, determine one or more deviations from the simulation data, and generate corrective actions. The corrective actions can be provided to an associated system (e.g., world state system, forecasting system, optimization/planning system, matching and fulfillment system, simulation system, vehicle provider system, etc.) to enable the system to make one or more modifications to correct the one or more deviations.

More specifically, the service entity computing system can receive a request from a rider that requests for the service entity computing system to facilitate a transportation service for the rider from an origin location to a destination location. In response to the request, the service entity computing system can generate at least one itinerary that includes transportation of the rider from the origin location to the destination location. The itinerary can include an end-to-end multi-modal transportation itinerary including a plurality of transportation legs that include transportation via a plurality of different transportation modalities. The end-to-end multi-modal transportation itinerary can include two or more transportation legs that include travel via two or more different transportation modalities such as, for example: cars, motorcycles, light electric vehicles (e.g., electric bicycles or scooters), buses, trains, aircraft (e.g., airplanes), watercraft, walking, and/or other transportation modalities. Example aircrafts can also include helicopters and other vertical take-off and landing aircraft (VTOL) such as electric vertical take-off and landing aircraft (eVTOL). The vehicles can include non-autonomous, semi-autonomous, and/or fully-autonomous vehicles.

The service entity computing system can perform one or more algorithms to generate a multi-modal transportation itinerary for the rider. For instance, the service entity computing system can sequentially analyze and identify potential transportation legs for each different available transportation modality. The service entity computing system can initially analyze a first transportation modality that is the most efficient (e.g., in terms of travel speed and/or cost) transportation modality which operates according to a fixed infrastructure. As an example, for most longer transportation services and for the mix of different modalities described above, flight modalities can both be the most efficient transportation modality (e.g., in terms travel speed/time) while also operating according to a fixed infrastructure. By first analyzing the most efficient transportation modality which operates according to a fixed infrastructure, the service entity computing system can seek to identify an important transportation leg around which the remainder of the itinerary can be stitched.

For example, the service entity computing system can identify a set of candidate transportation plans that can form the basis for building a set of potential itineraries and stitch additional transportation legs to each respective candidate transportation plan to generate a plurality of candidate end-to-end multi-modal transportation itineraries. The service entity computing system can analyze the candidate multi-modal transportation itineraries to select one or more multi-modal transportation itineraries that are high quality according to various measures. The service entity computing system can interact with one or more vehicle provider computing system(s) and/or other associated devices to facilitate at least one of the one or more multi-modal transportation itineraries.

At times, the service entity computing system can obtain the set of candidate transportation plans from a vehicle provider computing system. For example, the service entity computing system can collaborate with the vehicle provider computing system to obtain a set of candidate aerial transportation services. By way of example, the service entity computing system can utilize service entity vehicle(s) of a service entity fleet of aerial vehicles or vehicle provider vehicle(s) of a vehicle provider fleet of aerial vehicles to facilitate one or more aerial transportation services. The vehicle provider vehicle(s) can be managed, operated, and/or scheduled by a vehicle provider computing system, whereas the service entity computing system can be configured to manage, operate, and/or schedule the service entity vehicle(s).

The service entity computing system can obtain vehicle data (e.g., an availability and/or any other vehicle attributes associated with a vehicle) associated with the vehicle provider vehicle(s) and/or request one or more aerial transportation services from the vehicle provider computing system. In turn, the vehicle provider computing system can utilize one or more services (e.g., world state service, forecasting service, simulation service, verification service, etc.) provided by the service entity computing system to manage, maintain, and/or schedule the vehicle provider vehicle(s).

The vehicle provider computing system can be configured to manage, maintain, and schedule the fleet of aerial vehicles across a plurality of aerial transportation facilities based on vehicle data associated with the vehicles. For example, each aerial vehicle of the vehicle provider fleet of aerial vehicles can be associated with one or more vehicle models. Generally, each vehicle model can be indicative of one or more aerial vehicle attributes such as one or more operational capabilities and/or vehicle components associated with a respective vehicle of the fleet of aerial vehicles. The vehicle components can be associated with one or more component states and/or component models.

For example, a respective vehicle model can be indicative of one or more vehicle attributes of an aerial vehicle. The vehicle attributes for a respective aerial vehicle can identify a state (e.g., location, power level, etc.) of the vehicle at one or more time steps of the operational time period. As one example, the vehicle attributes for a respective vehicle can include one or more of battery health data (e.g., a current, predicted, etc. power level of the vehicle), vehicle health data (e.g., a state of one or more components of the vehicle), pilot data (e.g., a current, predicted, etc. available time of an operator of the vehicle), usage data (e.g., flight hours, etc.), or location data (e.g., current, predicted, etc. location of the vehicle) associated with the respective vehicle. In some implementations, for example, the vehicle model can be indicative of usage information (e.g., historical usage, current usage, expected usage, etc.) for a respective aerial vehicle. The usage data can be indicative historical, current, and/or expected flight time for the vehicle and/or the operator of the vehicle. In some cases, the current state of an aerial vehicle can be determined based at least in part on the usage data.

As another example, the vehicle attributes can include one or more operational capabilities, a list of components and/or types of components of the aerial vehicle, and/or a current state and/or health of each of the vehicle components. The vehicle components, for example, can include one or more hardware components and/or software components for each of the plurality of aerial vehicles. The hardware components can include at least one power components (e.g., an engine, fuel tank, battery, etc.), climate control components, navigation components, flight control components, etc. The one or more software components can include one or more software applications (e.g., an operating system, a user interface, etc.) associated with the aerial vehicle. The component state of each of the aerial components can identify a health (e.g., a power level, a current software version, etc.) of each of the one or more components. For example, the component state of a power component can identify a power level (e.g., fuel level, charge level, etc.) of the power component (e.g., battery, fuel tank, etc.) for a respective aerial vehicle.

In some implementations, the vehicle model can be associated with one or more component models. For example, the vehicle model can be associated with a battery model modelling one or more attributes of a battery of the aerial vehicle. For instance, the battery model can be indicative of one or more performance characteristic(s) of an electric battery of a respective aerial vehicle. The performance characteristics can be indicative of an expected long term performance (e.g., life expectancy) of the battery and/or an expected short term performance (e.g., charge level) of the battery. In addition, the performance characteristics can be indicative of maintenance (e.g., slow charge, fast charge, etc.) that can affect the expected long term and/or short term performance of the battery. The battery model can include structural information such as a type of cells used, the chemistry within each of the cells, an organizational structure of the cells, how cell modules are packed together, materials used that may affect the dissipation of heat, etc. In some implementations, the performance characteristics of the electric battery can be determined based, at least in part, on the structural information.

The vehicle provider and/or service entity computing system can determine one or more flight schedule(s) for one or more vehicles of a respective fleet of aerial vehicles based on the vehicle data. Each flight schedule can include one or more flight itineraries for each vehicle of the respective fleet of aerial vehicles. A flight itinerary, for example, can include one or more flight attributes. The one or more flight attributes can include a departure time, a departure location (e.g., the aerial transportation facility, a take-off location of the aerial transportation facility, etc.), a destination time (e.g., estimated time of arrival at a destination facility), a destination location, a vehicle capacity (e.g., number of passengers, etc.), a vehicle operator associated with the aerial transportation leg and/or any other information associated with the provision of an aerial transportation service.

The service entity computing system can utilize the plurality of service provider and/or service entity aerial vehicles for facilitating aerial transportation services for a number of riders based on the one or more flight schedules. To do so, the computing system can receive multi-modal transportation data indicative of one or more requests for a plurality transportation services and generate a plurality of multi-modal transportation itineraries for facilitating the plurality of transportation services. An aerial vehicle can be assigned to provide at least one leg of the multi-modal transportation itinerary based on a flight itinerary generated by the service entity computing system and/or obtained from the vehicle provider computing system. For example, the multi-modal transportation itinerary can include at least one aerial transportation leg. The aerial vehicle can be assigned to provide the at least one aerial transportation leg.

In some implementations, the aerial transportation leg can be selected from a ranked list of simulated aerial flight itineraries. For example, the simulation system can generate a plurality of simulated flight itineraries and simulate a plurality of aerial transportation services associated with the plurality of simulated flight itineraries. The plurality of simulated flight itineraries can be ranked according to one or more cost functions. At a respective timestep of a respective operational time period, the computing system(s) (e.g., via user input, one or more rules-based techniques, etc.) can receive a ranked list of simulated flight itineraries for the time step and select a simulated flight itinerary from the ranked list of simulated flight itineraries. The computing system(s) can initiate a real aerial transportation service based on the selected simulated flight itinerary and obtain operational data indicative of the performed flight itinerary.

For example, simulation data can be generated by the simulation system based on multi-modal transportation data, the candidate itinerary data, and/or the vehicle data. The simulation data can be indicative of a simulated flight itinerary. The simulated flight itinerary can be indicative of an expected performance of an aerial transportation service. In some implementations, the simulation data can include data indicative of a plurality of simulated flight itineraries for one or more operational time periods. The plurality of simulated flight itineraries can include one or more simulated flight itineraries previously generated for one or more time steps of each of the one or more operational time periods. As an example, the simulation data can be indicative of a plurality of simulated flight itineraries, each respective simulated flight itinerary of the plurality of simulated flight itineraries generated before a performance of a corresponding aerial transportation service at a respective time step of a respective operational time period. The respective simulated flight itinerary can be determined based, at least in part, on one or more operational constraints for the respective time step.

By way of example, each simulated flight itinerary can include a flight itinerary performed within a simulated word environment matching one or more expected conditions of the real world at a respective time step. The simulated world environment can be generated based on one or more operational constraints representing one or more real world attributes. The operational constraint(s) can be utilized to model the real world at one or more future time steps. The simulation system can determine the expected performance of an aerial transportation service by generating a simulated flight itinerary corresponding to the aerial transportation service and simulating the corresponding aerial transportation service within the simulated world environment.

Each simulated flight itinerary can be indicative of the expected performance of a respective aerial transportation service. By way of example, the expected performance of the aerial transportation service can include a plurality of expected performance parameters. The expected performance parameters, for example, can include an expected start time (e.g., boarding time, take-off time, etc.), an expected end time (e.g., landing time, deboarding time, etc.), an expected flight duration, an expected passenger capacity (e.g., number of passengers for a flight, seat assignments for the passengers, etc.), an expected weight distribution, an expected start location (e.g., origin aerial facility, take-off location, etc.), an expected route, and/or an expected destination location (e.g., destination aerial facility, landing pad, parking location, etc.).

The simulation data can be generated based on real time and predicted demand, supply, weather, and/or any other factor that can affect transportation services throughout an operational time period. The simulation system can simulate the plurality of flight itineraries for each time step throughout one or more operational time periods. For instance, at each respective time step, the simulation system can generate a plurality of flight itineraries based on real-time data (e.g., received from the world state service) up to the time step preceding the respective time step and/or prediction data (e.g., received from the forecasting service) for one or more time steps subsequent to the respective time step.

More particularly, the simulation computing system can generate the plurality of simulated itineraries based on operational constraints. The operational constraints can include at least one of one or more demand constraints, multi-modal itinerary constraints, vehicle constraints (e.g., the vehicle model), and/or one or more environmental constraints. For example, the simulation system can include and/or have access to one or more models (e.g., vehicle model, network model, candidate models, optimization model, etc.) configured to determine the one or more operational constraints. Each of the models can determine one or more constraints based on real time data. The real time data can be indicative of at least one of a number of requests for aerial transport services, one or more scheduled flight itineraries, vehicle data, and/or environment data at and/or up to a respective time step. The environmental data, for example, can be indicative of one or more environmental conditions at and/or up to the respective time step.

Each of the models can generate data for a respective time step based on the real time data obtained up to the respective time step. For instance, the demand model can estimate updated demand data for each respective time step of the operational time period based on a real-time demand (e.g., as indicated by requests for aerial transportation services, one or more scheduled flight itineraries, etc.) for aerial transport services at and/or up to the time step preceding the respective time step for which it is available. The simulation system can interact with each of the models (and/or systems including the models) to obtain operational constraints for each respective time step of the one or more operational time periods.

For example, the one or more operational constraints can include multi-modal transportation data indicative of one or more anticipated, real-time, and/or scheduled requests for aerial transportation services. The one or more requests can include one or more real-time requests received at a respective time step, one or more scheduled requests received at a time step preceding the respective time step and assigned to a scheduled multi-modal transportation itinerary (e.g., including a scheduled flight itinerary), and/or one or more anticipated requests for one or more time steps subsequent to the respective time step. The one or more anticipated requests can include an estimated number of requests that will be received at one or more time steps throughout an operational time period. For example, the multi-modal transportation data can include demand data indicative of a plurality of anticipated requests and/or one or more aspects thereof. For instance, the demand data can be indicative of the one or more anticipated transportation services throughout one or more operational time periods.

The service entity computing system (e.g., the forecasting system, etc.) can include and/or be associated with a network model configured to generate the multi-modal transportation data and/or a portion of the multi-modal transportation data. The network model can include one or more machine-learned models. For instance, the network model can include a demand model, a load modal, and/or an aerial transport usage model. The demand model can be configured to determine an anticipated demand for aerial transport services at one or more time steps throughout one or more operational time periods. The load model can be configured to estimate the maximum expected load factors at one or more time steps throughout the one or more operational time periods. And, the aerial transport usage model can be configured to estimate an expected number of flights for each aerial transport facility of the fixed transportation infrastructure at one or more time steps throughout the one or more operational time periods.

In some implementations, each of the models can be configured to interact with the vehicle provider computing system to make each respective prediction. For example, the vehicle provider computing system can provide vehicle data and/or any other data available to the vehicle provider computing system to one or more models of the service entity computing system. The one or more models of the service entity computing system can generate the predictions and provide the resulting multi-modal transportation data to the vehicle provider computing system for use in developing one or more flight itineraries.

The multi-modal transportation data can include a comprehensive overview of a number of services that can be fulfilled throughout an operational time period and/or one or more attributes of those services. For example, the multimodal transportation data can identify one or more types of services (e.g., time sensitive, capacity sensitive, etc.), one or more aerial transportation facilities associated with each of the services, a number of services that can be fulfilled for each transportation facility, etc. In some implementations, the multi-modal transportation data can include itinerary data. The itinerary data can include one or more multi-modal transportation itineraries for the one or more scheduled and/or anticipated aerial transportation services.

As another example, the one or more operational constraints can include candidate itinerary constraints indicative one or more potential flight itineraries at one or more time steps throughout one or more operational time periods. The one or more potential flight itineraries can be determined by the service entity computing system and/or obtained from a vehicle provider computing system. For example, the service entity computing system (e.g., optimization/planning system) can include and/or be associated with a candidate model configured to generate the candidate itinerary constraints. The candidate model can include one or more machine-learned models. The candidate model can be configured to determine a respective plurality of candidate flight itineraries for one or more time steps throughout the one or more operational time periods. For example, the candidate flight itineraries can include every possible flight plan between each of a number of aerial facilities at a respective time step.

In addition, or alternatively, the one or more operational constraints can include vehicle constraints and/or one or more environmental constraints. The vehicle constraints can be based on the one or more vehicle models associated with the plurality of aerial vehicles. For instance, the vehicle constraints can include the one or more operational constraints associated with one or more vehicles. In addition, or alternately, the vehicle constraints can include an availability constraint indicative of an availability of one or more of the plurality of vehicles at a respective time step. In some implementations, the vehicle constraints can include a current state of the one or more available vehicles and/or components thereof. The environmental constraints can be based on one or more weather models configured to predict one or more environmental conditions for each time step of each of the one or more operational time periods.

The plurality of simulated itineraries for each respective operational time period can be optimized in view of the respective operational time period. For example, the operational time period can include an operational day. The simulation system can generate a ranked list of simulated flight itineraries for a respective time step of a respective operational time period based on a plurality of simulated flight itineraries generated for the respective time step. To do so, the simulation system can determine contextual data for each of a plurality of simulated flight itineraries generated for the respective time step. The contextual data can be indicative of a relative impact of a respective simulated flight itinerary to one or more metrics associated with the operational time period. The one or more metrics, for example, can include an overall noise level, an overall profit margin, an overall ride quality, and/or any other measurement observed throughout an operational time period.

The relative impact of the respective simulated flight itinerary can be determined based, at least in part, on a plurality of subsequent simulated flight itineraries generated for one or more time steps subsequent to the respective time step. The plurality of subsequent simulated flight itineraries can be generated based, at least in part, on the respective simulated flight itinerary, and one or more operational constraints (e.g., an anticipated demand, a plurality of candidate flight itineraries, etc.) for the one or more time steps subsequent to the respective time step.

The simulation system can generate a ranked list of flight itineraries based, at least in part, on the contextual data for each of the plurality of simulated flight itineraries. Each simulated flight itinerary of the ranked list of flight itineraries can be ranked based, at least in part, on a relative impact of the simulated flight itinerary to one or more of the metrics for the operational time period. As an example, the simulated flight itineraries can be ranked according to a cost function configured to minimize a predicted overall noise level, maximize a predicted profit margin, and/or maximize a predicted overall ride quality for the plurality of flight itineraries scheduled during the operational time period.

The ranked list simulated flight itineraries (e.g., simulation data) can be provided to the service entity computing system (e.g., the optimization/planning service) and/or the vehicle provider computing system for use in generating a flight itinerary and/or a multi-modal transportation itinerary based on a flight itinerary. The computing system(s) can select a simulated flight itinerary from the ranked list of flight itineraries to facilitate an aerial transportation service for a rider. For example, the computing system(s) can obtain the ranked list of flight itineraries for a respective time step associated with a request for the aerial transportation service. In some implementations, the ranked list of flight itineraries can be provided for display (e.g., to one or more operators associated with the service entity computing system). In addition, or alternatively, one or more portions of the contextual data associated with each of the simulated flight itineraries of the ranked list of simulated flight itineraries can be provided for display.

The computing system(s) can select a flight itinerary for a transportation leg of the multi-modal transportation itinerary associated with the aerial transportation of the rider from the ranked list of flight itineraries. The selection of the selected flight itinerary can be performed automatically by the computing system (e.g., via a selection algorithm (e.g., based on rank and/or one or more other portions of the contextual data)) and/or by an operator of the computing system(s) (e.g., via user input). For example, the selection algorithm can include an automatic selection logic that selects a simulated flight itinerary based on one or more attributes (e.g., highest ranked itinerary, lowest ranked itinerary, etc.) of the contextual data accompanying the ranked list of simulated flight itineraries. In addition, or alternatively, the computing system(s) can receive user input indicative of a selection of the selected flight itinerary. The user input can be received via one or more input devices (e.g., microphone, tactile device (e.g., keyboard, mouse, button, etc.), etc.) of the computing system(s) and/or via one or more devices (e.g., rider devices, operator device, etc.) communicatively connected to the computing system(s).

The computing system(s) can initiate the performance of an aerial transportation service based on a selected itinerary. The computing system(s) can track the performance of the aerial transportation service and record operational data including a plurality of recorded performance parameters. The plurality of performance parameters can include at least one of an actual start time, an actual end time, an actual flight duration, an actual passenger capacity, an actual weight distribution, an actual start location, an actual route, and/or an actual destination location. In this manner, the computing system(s) can obtain data indicative of a performed flight itinerary. The performed flight itinerary can be indicative of the recorded performance of an aerial transportation service corresponding to a selected simulated flight itinerary. For example, each respective performed flight itinerary can correspond to the corresponding aerial transportation service at a respective time step of the respective operational time period.

The service entity computing system (e.g., verification system) can analyze simulation data generated over a number of operational time periods and operational data recorded over a number of operational time periods to identify one or more performance deviations between the simulation data and the operational data. For example, the computing system can obtain simulation data indicative of a simulated flight itinerary and operational data indicative of a performed flight itinerary. The simulation data can be indicative of a plurality of simulated flight itineraries for one or more operational time periods. The operational data can be indicative of a plurality of performed flight itineraries during the one or more operational time periods.

The plurality of simulated flight itineraries can include one or more selected itineraries, one or more provided itineraries, and/or one or more discarded itineraries. For example, the one or more provided itineraries can include a plurality of ranked lists of simulated flight itineraries for one or more time steps throughout one or more operational time periods. The one or more discarded itineraries can include one or more simulated flight itineraries that were generated but discarded (e.g., due to a low rank, etc.) and not included in a respective ranked list of simulated flight itineraries. As discussed herein, each ranked list of simulated flight itineraries can be ranked according to one or more cost functions and each respective ranked list of simulated flight itineraries can include contextual data for each respective simulated flight itinerary of the respective ranked list. In some implementations, each respective selected itinerary of the one or more selected itineraries can be selected from a respective ranked list of simulated flight itineraries. The operational data can be indicative of a plurality of performed flight itineraries including a respective performed flight itinerary for each of the one or more selected itineraries.

The computing system can determine one or more performance deviations associated with a simulated flight itinerary based, at least in part, on the simulation data and the operational data. For example, the computing system can determine the performance deviations based on the recorded performance of an aerial transportation service corresponding to the simulated flight itinerary. The one or more performance deviations are indicative of one or more differences between the plurality of recorded performance parameters and the plurality of expected performance parameters. By way of example, a performance deviation can include one or more time differences (e.g., the simulated boarding, take-off, landing, de-boarding, etc. time is later, earlier, etc. than a recorded counterpart), one or more vehicle state differences (e.g., the simulated vehicle state such as a predicted power level at one or more time points is higher/lower than a recorded power level, etc. at the respective one or more time points), and/or any other deviation from a simulated/expected performance of a transportation service.

The computing system can generate one or more corrective actions based, at least in part, on the one or more performance deviations. The corrective action(s) can be associated with at least one of a generation of the simulated flight itinerary and/or a selection of the simulated flight itinerary. For example, the corrective action can include a modification to one or more of the operational constraint(s) (and/or the determination thereof) utilized by the simulation system to generate the simulated flight itineraries. As an example, the modification can include a modification to one or more of the models (e.g., vehicle models, network models, demand models, load models, usage models, candidate models, etc.) configured to generate one or more of the operational constraints. In addition, or alternatively, the corrective action can include a modification to one or more cost functions utilized to rank the one or more simulated flight itineraries, an order in which to rank the simulated flight itinerary(s), portions of contextual data that are provided with the simulated flight itinerary(s), and/or any other aspect associated with selecting a simulated flight itinerary for facilitating a multi-modal transportation itinerary.

For example, to generate a corrective action, the computing system can identify a shared performance deviation associated with one or more of the plurality of simulated flight itineraries based, at least in part, on the operational data. A shared performance deviation can include a common performance deviation across a plurality of simulated flight itineraries. Each performance deviation can be indicative of an expected performance parameter that is consistently different than a recorded performance parameter for a plurality of simulated/recorded flight itineraries. By way of example, the shared performance deviation can include a plurality of simulated times (e.g., estimated arrival time, etc.), weight distributions, passengers, routes, etc. across a plurality of simulated itineraries that are consistently different than a recorded time, weight distribution, passengers, routes, etc. for scheduled flights based on the simulated flight itineraries. For instance, a shared performance deviation can identify a plurality of simulated flight itineraries with estimated times of arrival that deviate from a plurality of recorded times of arrival for a plurality of scheduled flight itineraries corresponding to the simulated flight itineraries.

The computing system can determine one or more correlating parameters of the one or more simulated flight itineraries associated with the shared performance deviation. The correlating parameter(s) can include one or more performance parameters (e.g., expected, recorded, etc.) and/or operational constraints associated with each of the one or more simulated flight itineraries. By way of example, the correlating parameter(s) can include one or more expected and/or recorded parameters (e.g., time, weight distribution, passengers, routes, etc.) shared by each of the simulated flight itineraries associated with the shared performance deviation. In addition, the correlating parameter(s) can include one or more operational constraints shared by each of the simulated flight itineraries associated with the shared performance deviation. By way of example, the one or more shared operational constraints can include a demand constraint, multi-modal itinerary constraint, vehicle constraint (e.g., a vehicle model), environmental constraint, etc. that are used to generate each of the simulated flight itineraries.

The computing system can generate a corrective action for the shared performance deviation based, at least in part, on the one or more correlating parameters. By way of example, a correlating parameter can include an operational constraint. In addition, or alternatively, the correlating parameter can include a shared performance parameter indicative of an operational constraint (e.g., a flight time can be indicative of a vehicle model, etc.). In such a case, the corrective action for the shared performance deviation can be indicative of a modification to the determination of the operational constraint (e.g., by modifying one or more parameters of a model/function associated with the operational constraint).

As an example, the operational constraint can be a vehicle constraint determined based, at least in part, on a vehicle model indicative of a plurality of vehicle attributes. In such a case, the modification to the determination of the vehicle constraint can include a modification to at least one of the plurality of vehicle attributes. As another example, at least one of the one or more correlating parameters can be indicative of an aerial vehicle provider. In such a case, the corrective action for the shared performance deviation can include associating the shared performance deviation with the aerial vehicle provider. This can include, for example, modifying one or more parameters of a vehicle model associated with the aerial vehicle provider, etc.

In addition, or alternatively, the computing system can generate a corrective action indicative of a change to the ranking of future simulated flight itineraries and/or the contextual data associated therewith. For example, the corrective action can include a modification to at least one of the one or more cost functions utilized to rank the simulated flight itineraries. The modification, for example, can modify one or more parameters of the cost function(s) to prioritize one or more different metrics associated with an operational time period. By way of example, the computing system can determine, based on the one or more performance deviations, that an optimal simulated flight itinerary is consistently ignored (e.g., an optimal flight itinerary is discarded based on a low ranking, or provided but ignored by the selecting operator or system). In such a case, the computing system can determine one or more corrective actions to alter the rankings of future simulated flight itineraries to reduce the chances that the optimal simulated flight itinerary is ignored.

As another example, the computing system can generate a corrective action indicative of a change to the contextual data and/or portions thereof that are provided with each simulated flight itinerary of a ranked list of simulated flight itineraries. For instance, contextual data can be determined for each respective simulated flight itinerary based, at least in part, on one or more selection criteria. The selection criteria can prioritize one or more portions of the contextual data (e.g., an estimated noise level, etc.). The computing system can determine that one or more different portions of contextual data are more desirable and/or can lead to the selection of a more optimal itinerary. In such a case, the corrective action can include a modification to the one or more selection criteria and, thus, the one or more portions of contextual data provided with each simulated flight itinerary.

In some implementations, the computing system can obtain feedback data associated with the selection of a simulated flight itinerary. The feedback data can include user input or metadata (e.g., number of clicks, time before selection, etc.) associated with the user input. The computing system can generate the one or more corrective actions based, at least in part, on the feedback data. For example, the computing system can determine one or more portions of contextual data and/or a ranking that aid in the selection of an optimal simulated itinerary based, at least in part on the feedback data.

The computing system can output the one or more corrective actions to a user and/or one or more systems (e.g., world state system, forecasting system, optimization/planning system, vehicle provider system, etc.) associated with the generation and/or selection of multi-modal transportation itineraries. For example, the one or more corrective actions can include recommendations to make one or more modifications to one or more models, functions, services, etc. provided by the one or more systems. A respective system (and/or user thereof) can obtain the recommendations and determine whether to implement the modification by modifying one or more parameters of a corresponding model, function, service, etc.

In some implementations, the computing system can provide data indicative of the one or more corrective actions to the respective system. The data can be indicative of at least one modification to the generation of a simulated flight itinerary or a selection of a simulated flight itinerary and a predicted impact of the at least one modification (e.g., a predicted reduction of the performance deviation, etc.). As an example, the data indicative of the one or more corrective actions can include a recommended modification, an object (e.g., model, function, service, etc.) associated with the modification, and/or the predicted impact of the modification. The respective system (and/or user thereof) can obtain the data indicative of the one or more corrective actions and determine whether to implement the associated recommended modifications based on the predicted impact of the recommended modifications. For example, the system can automatically determine whether to implement a modification based, at least in part, on a threshold impact. In the event that the predicted impact achieves the threshold impact, the respective system can be configured to implement the modification. The respective system can implement a modification by modifying the object (e.g., one or more parameters of a model, function, service, etc.) associated with the corrective action.

As another example, the one or more corrective actions can be provided for display, via one or more display devices, to a user of a respective system. By way of example, the computing system can provide for display, via the one or more display devices, data indicative of the one or more corrective actions. The user of the respective system can select at least one of the one or more corrective actions. In response, the respective system can implement the modification associated with the selected corrective action.

Example aspects of the present disclosure can provide a number of improvements to computing technology such as, for example, multi-modal transportation technology. For instance, the systems and methods of the present disclosure provide an improved approach for optimizing the real-time provisioning of multi-modal transportation itineraries over an operational time period. In particular, the systems and methods of the present disclosure can improve multi-modal simulation and scheduling systems by enabling the systems to identify and correct deviations between a simulation and the performance of a multi-modal transportation itinerary. These improvements can be realized by determining shared performance deviations between a number of simulations and a number of corresponding recorded aerial transportation services over time, generating corrective actions based on the shared performance deviations, and providing the corrective actions to a computing system for implementation. By generating corrective actions for a computing system as disclosed herein, the systems and methods of the present disclosure can increase the accuracy of computing systems over time based on the use of the systems. This can include the improvement of simulation tools for optimizing itinerary selection. In this manner, the systems and methods of the present disclosure can enable a service entity configured to provide a multi-modal transportation service to simulate increasingly realistic multi-modal transportation itineraries that optimize one or more aspects of an operational time period. Such simulations can be scheduled to reduce the computing resources expended providing multi-modal transportation services.

For example, a computing system can obtain simulation data indicative of a simulated flight itinerary. The computing system can obtain operational data indicative of a performed flight itinerary of the multi-modal transportation itinerary. The computing system can determine one or more performance deviations associated with the simulated flight itinerary based, at least in part, on the simulation data and the operational data. The computing system can generate one or more corrective actions based, at least in part, on the one or more performance deviations. And, the computing system can output the one or more corrective actions to a respective user or computing system. In this way, the computing system employs improved simulation and verification techniques to improve the accuracy of simulated multi-modal transportation itineraries. To do so, the computing system accumulates and distributes newly available information such as, for example, the one or more corrective actions. By leveraging such data, the computing system can implement modifications to one or more aspects of the generation and selection of multi-modal transportation itineraries that improve the accuracy of simulations and optimize scheduled itineraries over time.

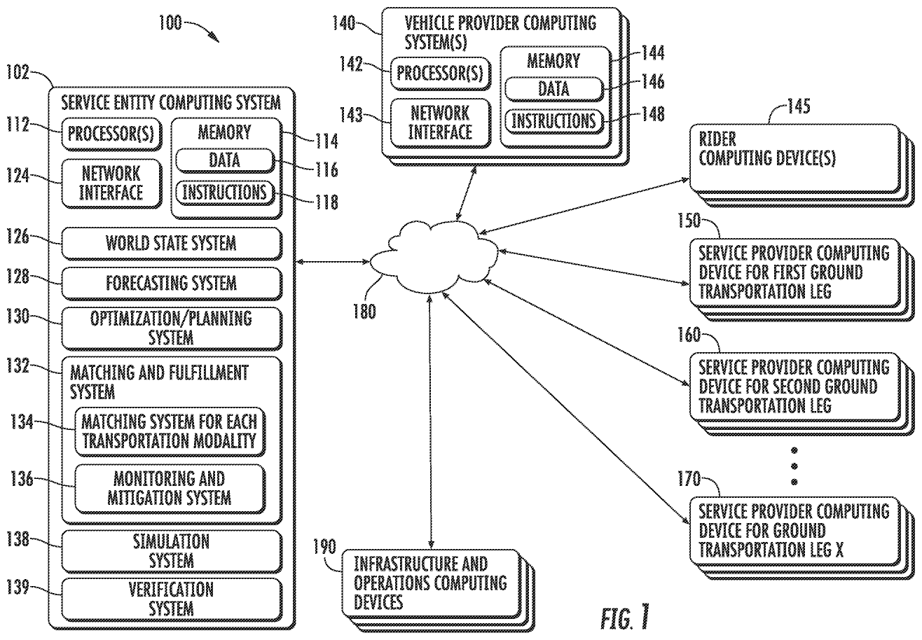

FIG. 1 depicts a block diagram of an example computing system 100 according to example embodiments of the present disclosure. The system 100 can include a service entity computing system 102 and a vehicle provider computing system 140 that can operate (e.g., collectively or individually) to control, route, monitor, and/or communicate with aircraft (e.g., VTOL aircraft) and/or one or more other transportation service entities to facilitate a multi-modal transportation service. These operations can be performed as part of a multi-modal transportation service for riders, for example, including travel by ground vehicle and travel by aircraft (e.g., VTOL aircraft).

The service entity computing system 102 can be communicatively connected over a network 180 to the vehicle provider computing system(s) 140, one or more rider computing devices 145, one or more service provider computing devices 150 for a first ground transportation leg, one or more service provider computing devices 160 for a second ground transportation leg, one or more service provider computing devices 170 for an Nth ground transportation leg, and/or one or more infrastructure and operations computing devices 190. For example, the vehicle provider computing system(s) 140 can include one or more communication interfaces 143 communicatively connected to the service entity computing system 102 and the service entity computing system 102 can include one or more communication interfaces 124 communicatively connected to the vehicle provider computing system(s) 140.

For example, the network(s) 180 can be any type of network or combination of networks that allows for communication between devices. In some embodiments, the network(s) 180 can include one or more of a local area network, wide area network, the Internet, secure network, cellular network, mesh network, peer-to-peer communication link and/or some combination thereof and can include any number of wired or wireless links. Communication over the network(s) 180 can be accomplished, for instance, via a network interface using any type of protocol, protection scheme, encoding, format, packaging, etc.

Each of the computing devices 145, 150, 160, 170, 190 can include any type of computing device such as a smartphone, tablet, hand-held computing device, wearable computing device, embedded computing device, navigational computing device, vehicle computing device, etc. A computing device can include one or more processors and a memory (e.g., similar to as will be discussed with reference to processors 112, 142 and memory 114, 144). Although service provider devices are shown for N different transportation legs, any number of different transportation legs can be used, including, for example, less than the three illustrated legs (e.g., two legs can be used).

The computing systems 102, 140 can include one or more processors 112, 142 and a memory 114, 144. The one or more processors 112, 142 can be any suitable processing device (e.g., a processor core, a microprocessor, an ASIC, a FPGA, a controller, a microcontroller, etc.) and can be one processor or a plurality of processors that are operatively connected. The memory 114, 144 can include one or more non-transitory computer-readable storage media, such as RAM, ROM, EEPROM, EPROM, one or more memory devices, flash memory devices, etc., and combinations thereof.

The memory 114, 144 can store information that can be accessed by the one or more processors 112, 142. For instance, the memory 114, 144 (e.g., one or more non-transitory computer-readable storage mediums, memory devices) can store data 116, 146 that can be obtained, received, accessed, written, manipulated, created, and/or stored. In some implementations, the computing system(s) 102, 140 can obtain data from one or more memory device(s) that are remote from the system(s) 102, 140.

The memory 114, 144 can also store computer-readable instructions 118, 148 that can be executed by the one or more processors 112, 142. The instructions 118, 148 can be software written in any suitable programming language or can be implemented in hardware. Additionally, or alternatively, the instructions 118, 148 can be executed in logically and/or virtually separate threads on processor(s) 112, 142. For example, the memory 114, 144 can store instructions 118, 148 that when executed by the one or more processors 112, 142 cause the one or more processors 112, 142 to perform any of the operations and/or functions described herein.

The service entity computing system 102 can include a number of different systems such as, for example, a world state system 126, forecasting system 128, optimization/planning system 130, matching and fulfillment system 132, simulation system 138, and/or verification system 139 that can help plan and fulfill one or more portions of a multi-modal transportation service. Each system can provide one or more backend services of the service entity computing system 102 to the one or more vehicle provider computing system(s) 140 and/or other associated devices 145, 150, 160, 170, 190. For example, the world state system 126 can provide a backend world state service, the forecasting system 128 can provide a backend forecasting service, the optimization/planning system 130 can provide a backend scheduling service, the matching and fulfillment system 132 can provide an assignment service, the simulation system 138 can provide a simulation service, and/or the verification system 139 can provide a verification service. The systems 126-139 can cooperatively interoperate (e.g., including supplying information to each other).

By way of example, the world state system 126 can operate a state monitoring service to maintain data descriptive of a current state of the world. The state monitoring service can generate, collect, and/or maintain data descriptive of planned itineraries; scheduled transportation plans (e.g., flight itineraries) and assignments; current service requests; current ground transportation service providers; current aerial transport facility operational statuses (e.g., including re-charging or re-fueling capabilities); current aerial vehicle statuses (e.g., including current fuel or battery level); current pilot statuses; current flight states and trajectories; current airspace information; current weather conditions; current communication system behavior/protocols; and/or the like. Such data can be obtained through communication (e.g., via an API platform) with one or more systems (e.g., vehicle provider computing system(s) 140) and/or devices 145, 150, 160, 170, 190 associated with the service entity computing system 102.

The forecasting system 128 can operate a forecasting service to generate predictions of transportation demand, weather forecasts, and/or any other future looking data helpful for completing a transportation service. As an example, the forecasting system 128 can generate predictions of demand and supply for transportation services at or between various locations over time. The forecasting system 128 can also generate or supply weather forecasts. The predictions made by the forecasting system 128 can be generated based on historical data and/or through modeling of supply and demand.

The optimization/planning system 130 can operate a scheduling service to generate and/or obtain (e.g., from the vehicle provider computing system(s) 140) transportation plans for various transportation assets. For example, the optimization/planning system 130 can perform and/or facilitate route planning, flight planning, and/or multi-modal transportation planning. As another example, optimization/planning system 130 can plan or manage/optimize itineraries which include interactions between riders and service providers or vehicle providers across multiple modes of transportation. The matching and fulfillment system 132 can operate an assignment service to match a rider with a service provider and/or a vehicle provider for each of the different transportation legs of a multi-modal transportation itinerary. For example, each respective matching system 134 can communicate with the corresponding service provider computing devices 150, 160, 170 via one or more APIs or connections. Each matching system 134 can communicate trajectories and/or assignments to the corresponding service providers or vehicle providers. Thus, the matching and fulfillment system 132 can perform or handle assignment of ground transportation, flight trajectories, take-off/landing, etc.

The monitoring and mitigation system 136 can perform monitoring of rider itineraries and can perform mitigation when an itinerary is subject to significant delay (e.g., one of the legs fails to succeed). Thus, the monitoring and mitigation system 136 can perform situation awareness, advisories, adjustments and the like. The monitoring and mitigation system 136 can trigger alerts and actions sent to the devices 140, 145, 150, 160, 170, and 190. For example, entities such as riders, service providers, and/or operations personnel can be alerted when a certain transportation plan has been modified and can be provided with an updated plan/course of action. Thus, the monitoring and mitigation system 136 can have additional control over the movement of aerial vehicles, ground vehicles, air traffic controllers, pilots, and riders.

The simulation system 138 can operate a simulation service to generate and simulate, within a simulated world environment, a plurality of different multi-modal and/or flight itineraries at one or more different time steps throughout an operational time period. The optimization/planning system 130, the matching and fulfillment system 132, and/or the vehicle provider computing system(s) 140 can leverage the simulation data output by the simulation service to generate, schedule, assign, and/or fulfill a multi-modal transportation itinerary and/or one or more portions of a multi-modal transportation itinerary (e.g., an aerial transportation leg).

As described herein, the verification system 139 can operate a verification service that can obtain simulation and operational data, determine one or more deviations from the simulation data, and generate corrective actions. The corrective actions can be provided to an associated system (e.g., world state system 126, forecasting system 128, optimization/planning system 130, matching and fulfillment system 132, simulation system 138, vehicle provider computing system 140, etc.) to enable the system to make one or more modifications to correct the one or more deviations.

The service entity computing system 102 can receive a request from a rider that requests for the service entity computing system 102 to facilitate a transportation service for the rider from an origin location to a destination location. For example, the rider can interact with a dedicated application on the rider computing device 145 (e.g., smartphone, tablet, wearable computing device, or the like) to initiate the request. By way of example, the rider can interact with the rider computing device 145 by opening the dedicated application and/or initiating a booking process via the dedicated application. The service entity computing system 102 can initiate the generation of a plurality of multi-modal transportation itineraries in response to the rider opening the dedicated application and/or otherwise initiating a booking process.

In response to the request, the service entity computing system 102 can generate at least one itinerary that includes transportation of the rider from the origin location to the destination location. Specifically, the service entity computing system 102 can generate an end-to-end multi-modal transportation itinerary including a plurality of transportation legs that include transportation via a plurality of different transportation modalities. The end-to-end multi-modal transportation itinerary can include two or more transportation legs that include travel via two or more different transportation modalities such as, for example: cars, motorcycles, light electric vehicles (e.g., electric bicycles or scooters), buses, trains, aircraft (e.g., airplanes), watercraft, walking, and/or other transportation modalities. Example aircrafts can also include helicopters and other vertical take-off and landing aircraft (VTOL) such as electric vertical take-off and landing aircraft (eVTOL). The vehicles can include non-autonomous, semi-autonomous, and/or fully-autonomous vehicles.

The service entity computing system 102 and/or the vehicle provider computing system 140 can facilitate the ability of the rider to receive transportation on one or more of the transportation legs included in the multi-modal transportation itinerary. As one example, the service entity computing system 102 can interact with one or more service provider computing device(s) 150, 160, 170 to match the rider with one or more transportation service providers. As another example, the service entity computing system 102 can book or otherwise reserve a seat in, space on, or usage of one or more of the transportation modalities for the rider. Additionally, or alternatively, the service entity computing system 102 can collaborate with the vehicle provider computing system 140 to provide information for options to be provided by the vehicle provider computing system 140 for one or more of the transportation legs.

More particularly, in some implementations, the service entity computing system 102 can respond to the rider's request by determining whether it is better to fulfill the rider's request using a single transportation modality or using multiple transportation modalities. As one example, the service entity computing system 102 can evaluate the rider's current location, origin location, and/or destination location to determine which modalities of transportation are usable at such location (e.g., able to access such locations). For example, the location(s) can be checked against a list of permitted locations that have been approved for participation in various types of modalities (e.g., flight modalities for the purpose of generating a multi-modal trip itinerary). As another example, the service entity computing system 102 can evaluate (e.g., generate) one or more itineraries that are single-modal and one or more itineraries that are multi-modal (e.g., inclusive of various combinations of different transportation modalities). The service entity computing system 102 can compare the generated single- and multi-modal itineraries to determine whether it is appropriate to suggest a single- or multi-modal itinerary to the rider. For example, one or more of the best itineraries (e.g., as evaluated based on various characteristics such as cost, time, etc.) can be suggested to the rider. The rider can select, via the rider computing device 145, one of the suggested itineraries to receive transportation services in accordance with the selected itinerary.

In some implementations, the service entity computing system 102 can continually re-evaluate various itineraries (e.g., single- and/or multi-modal itineraries) before a trip starts and even during the trip of a selected itinerary. If an improved itinerary becomes available (e.g., which may include changing from a single-modal itinerary to a multi-modal itinerary if, for example, a seat on a flight becomes available) the service entity computing system 102 can suggest the improved itinerary for selection by the rider. In some implementations, if the rider selects, via the rider computing device(s) 145, the improved itinerary during completion of a trip of an existing itinerary, the service entity computing system 102 (and/or the vehicle provider computing system 140) can facilitate switching to the updated itinerary, including, for example, re-routing a service provider that is currently transporting the rider to an alternative, updated destination.

Thus, in response to the rider's request, the service entity computing system 102 can perform one or more algorithms to generate and facilitate a multi-modal transportation itinerary for the rider. As an example, in some implementations, the service entity computing system 102 can sequentially analyze and identify potential transportation legs for each different available transportation modality. For example, a critical, challenging, and/or supply-constrained transportation leg can be identified first and then the remainder of the itinerary can be stitched around such leg. In some implementations, the order of analysis for the different modalities can be a function of a total distance associated with the transportation service (e.g., shorter transportation services result in ground-based modalities being assessed first while longer transportation services result in flight-based modalities being assessed first).

As one particular example, in some implementations, the service entity computing system 102 can initially analyze a first transportation modality that is the most efficient (e.g., in terms of travel speed and/or cost) transportation modality which operates according to a fixed infrastructure. As an example, for most longer transportation services and for the mix of different modalities described above, flight modalities can both be the most efficient transportation modality (e.g., in terms travel speed/time) while also operating according to a fixed infrastructure. By first analyzing the most efficient transportation modality which operates according to a fixed infrastructure, the service entity computing system 102 can seek to identify an important transportation leg around which the remainder of the itinerary can be stitched.

More particularly, in some implementations, one or more of the transportation modalities can operate according to or within a fixed transportation infrastructure in which the ability of passengers to embark and disembark vehicles is constrained to a defined set of transportation nodes. As one example, in some implementations, aerial vehicles that operate within the ride sharing network can be constrained to load and unload passengers only at a defined set of physical take-off and/or landing areas which may in some instances be referred to as aerial transportation facilities. To provide an example, a large urban area may have dozens of transportation nodes located at various locations within the urban area.

Each transportation node can include one or more landing pads and/or other infrastructure to enable passengers to embark or disembark from aerial vehicles. Transportation nodes can also include charging equipment, re-fueling equipment, and/or other infrastructure for enabling aerial operation. The infrastructure and operations computing devices 190, for example, can be any form of computing device used by or at the infrastructure or operations personnel including, for example, devices configured to perform passenger security checks, luggage check in/out, re-charging/re-fueling, vehicle climate control, vehicle check in/out, and/or the like. The take-off and/or landing areas of the transportation nodes can be located at ground level and/or elevated from ground-level (e.g., atop a building). The defined set of physical take-off and/or landing areas can include, for example, one or more public or private airports.

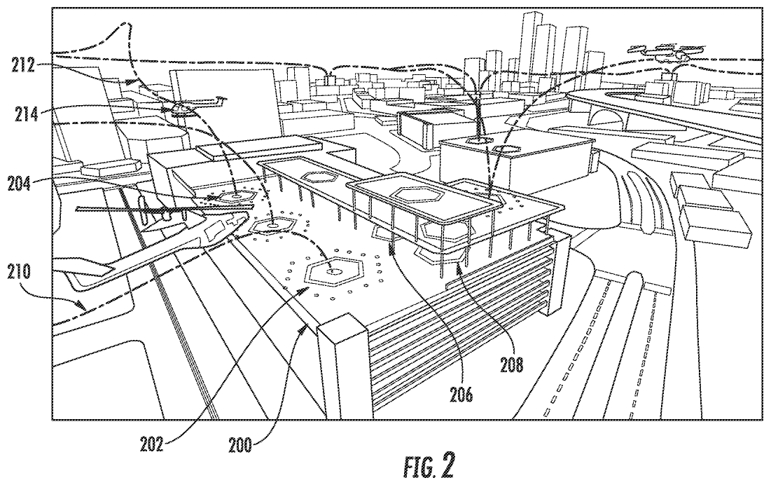

By way of example, FIG. 2 depicts a graphical diagram of an example transportation node according to example embodiments of the present disclosure. The example transportation node 200 can include a number of take-off/landing pads such as pads 202 and 204. In addition, the example transportation node 200 can include a number of vehicle parking locations such as parking locations 206 and 208. For example, re-fueling or re-charging infrastructure may be accessible at each parking location.

Flight trajectories into and out of the transportation node 200 can be defined, configured, assigned, communicated, etc. FIG. 2 illustrates a number of flight trajectories including, for example, trajectories 210 and 212. The trajectories can be fixed or can be dynamically computed. The trajectories can be computed by the aircraft or can be centrally computed and then assigned and communicated to the aircraft. As one example, FIG. 2 illustrates a helicopter 214 taking off from the pad 204 according to the trajectory 212.

Turning back to FIG. 1, the service entity computing system 102 can initially analyze the transportation modality that is the most supply-constrained. More particularly, certain transportation modalities may be more supply-constrained than other modalities in terms of number of available service providers and/or average number of services provided daily. For example, flight modalities may be more supply-constrained than ground-based modalities such as cars. Because the most supply-constrained modality represents the most option-limiting aspect of building different itineraries, by first analyzing the most supply-constrained modality the service entity computing system 102 can more efficiently generate the multi-modal transportation itinerary.

The service entity computing system 102 can initially identify any fixed transportation nodes (e.g., aerial transportation facilities) associated with a transportation modality (e.g., aerial transportation modality) that are relevant to the rider's request. For example, the service entity computing system 102 can identify any nodes that are within a threshold distance from the origin location as candidate departure nodes. Likewise, the service entity computing system 102 can identify any nodes that are within a threshold distance from the destination location as candidate arrival nodes.

In some instances, the service entity computing system 102 may have at least some control over transportation services provided by service providers on at least some of the transportation modalities and, therefore, may pre-determine a number of planned transportation services by the service providers. For example, in some implementations, the operators of one or more aerial vehicles can be controlled by (e.g., contracted with) the service entity computing system 102. In such a case, the service entity computing system 102 can generate (e.g., on a daily basis) an initial pre-defined set of flight plans for service entity aerial vehicles and can add or remove passengers from each planned flight. In addition, the service entity computing system 102 can dynamically optimize planned transportation services by the service entity to account for real-time changes in rider availability and demand. For example, the service entity computing system 102 can dynamically modify the pre-determined flight plans (e.g., delay a planned flight departure by five minutes and/or change a planned flight to an alternative arrival transportation node).

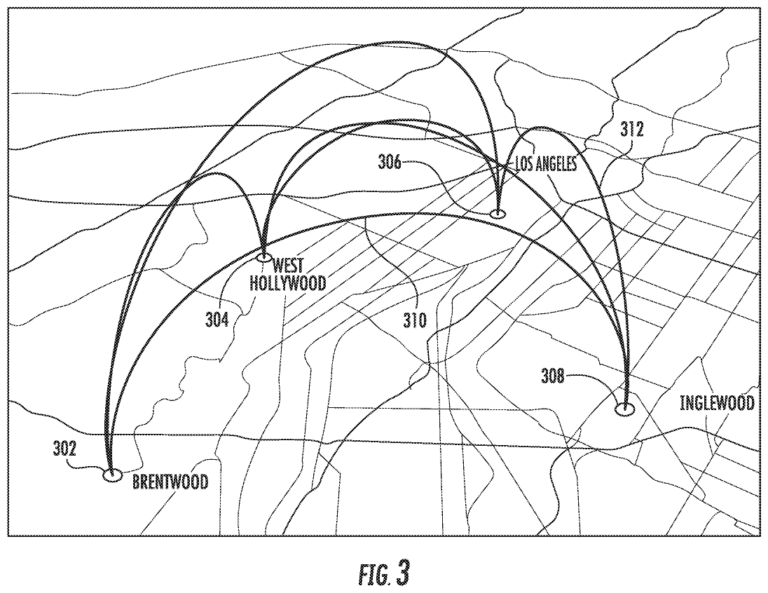

As an example, FIG. 3 depicts a graphical diagram of an example set of flight plans between an example set of transportation nodes according to example embodiments of the present disclosure. In particular, FIG. 3 provides a simplified illustration of an example fixed infrastructure associated with flight-based transportation in an example metropolitan area. As illustrated in FIG. 3, there can be four transportation nodes which may be referred to as “aerial transportation facilities.” For example, a first transportation node 302 is located in a first neighborhood of the metropolitan area, a second transportation node 304 is located in a second neighborhood, a third transportation node 306 is located in a third neighborhood, and a fourth transportation node 308 is located in a fourth neighborhood. The location and number of transportation nodes is provided only as an example. Any number of transportation nodes at any different locations can be used.

Flights can be available (e.g., may be pre-planned, dynamically planned, etc.) between certain pairs of the transportation nodes. For example, a flight path 310 can exist between the first transportation node 302 and the fourth transportation node 308. Likewise, a flight path 312 can exist between the fourth transportation node 308 and the third transportation node 306.

Turning back to FIG. 1, service entity computing system 102 can identify a set of candidate transportation plans that can form the basis for building a set of potential itineraries. As described in further detail herein, the set of candidate transportation plans can include each possible transportation itinerary between each node of the fixed transportation infrastructure at a respective time. The service entity computing system 102 can stitch additional transportation legs to each respective candidate transportation plan to generate a plurality of candidate end-to-end multi-modal transportation itineraries. The service entity computing system 102 can analyze the candidate end-to-end multi-modal transportation itineraries to select one or more itineraries that are high quality according to various measures. The service entity computing system 102 can interact with one or more vehicle provider computing system(s) 140 and/or service provider computing device 150, 160, 170 to facilitate at least one of the one or more multi-modal transportation itineraries.

In addition, or alternatively, the service entity computing system 102 can obtain a set of candidate transportation plans from a vehicle provider computing system 140. For example, the service entity computing system 102 can collaborate with the vehicle provider computing system 140 to obtain a set of candidate aerial transportation services. The vehicle provider computing system 140 can include a third-party computing system associated with a fleet of aerial vehicles capable of providing aerial transportation services for riders associated with the service entity computing system 102. For instance, the vehicle provider computing system 140 can include one or more communication interfaces 143 communicatively connected to the service entity computing system 102 such that the vehicle provider computing system 140 can exchange information to collaboratively generate and facilitate multi-modal transportation services.

For example, the service entity computing system 102 can obtain vehicle data (e.g., an availability and/or any other vehicle attributes associated with a vehicle) associated with a plurality of vehicles of the vehicle provider computing system 140 and/or request one or more aerial transportation services from the vehicle provider computing system 140. In turn, the vehicle provider computing system 140 can utilize one or more services (e.g., world state service, forecasting service, simulation service, verification service, etc.) provided by the service entity computing system 102 to manage, maintain, and/or schedule the vehicle provider vehicle(s).

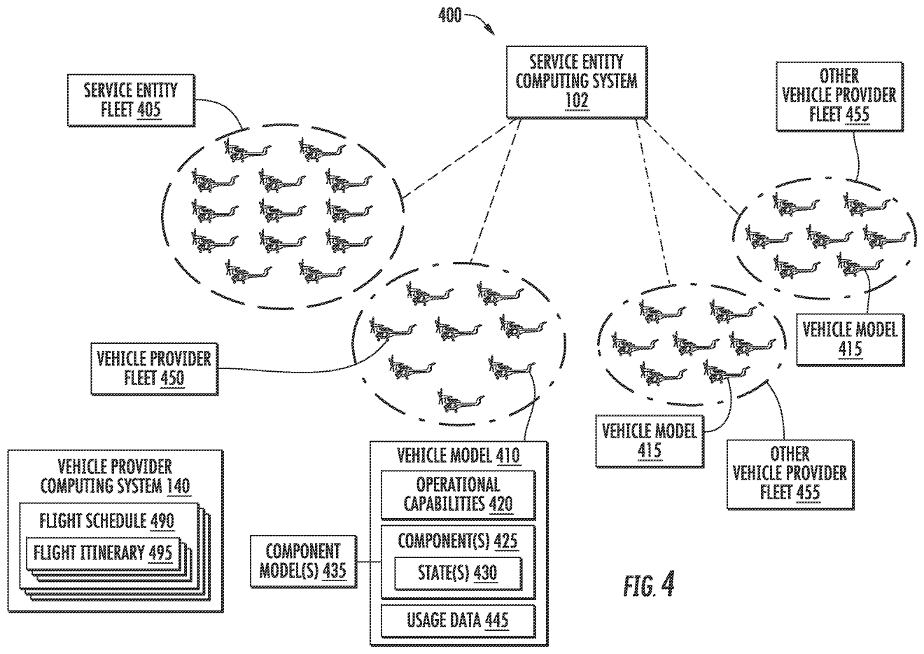

As an example, FIG. 4 depicts an example vehicle provider ecosystem 400 according to example embodiments of the present disclosure. The service entity computing system 102 can utilize service entity vehicle(s) of the service entity fleet 405 and/or one or more vehicle(s) from one or more third-party aerial vehicle provider(s) fleets 450, 455 to perform one or more aerial transportation services (e.g., throughout an operational time period such as an hour, day, week, etc.). The number of aerial vehicles available from the one or more third-party aerial vehicle providers (e.g., vehicle provider associated with vehicle provider computing system 140) can be independently available to a plurality of different ride-sharing platforms.

For example, a vehicle provider (associated with vehicle computing system 140) and the other aerial vehicle providers can be associated with a vehicle provider fleet 450 and/or a respective other vehicle provider fleet 455. Each fleet 450, 455 can include one or more aerial vehicles associated (e.g., managed, operated, scheduled, etc.) with a respective vehicle provider. The aerial vehicle(s) can include one or more autonomous, semi-autonomous, and/or non-autonomous aerial vehicles. The vehicle(s) can include any type of aircraft such as, for example, helicopters and/or other vertical take-off and landing aircraft (VTOL) including electric vertical take-off and landing aircraft (eVTOL). For instance, the vehicles can include one or more electric vehicles such as, for example, electric vertical and take-off and landing vehicles. The electric vehicles can be powered by one or more electric batteries.

The vehicle provider computing system 140 can be configured to manage, maintain, and schedule the fleet of aerial vehicles 450 across a plurality of aerial transportation facilities based on information associated with the vehicles. As described in further detail below, the fleet of aerial vehicles can be associated with one or more vehicle models 410, 415. The vehicle models 410, 415 can be indicative of one or more aerial vehicle operational capabilities 420, vehicle components 425, or usage data 445 associated with each vehicle of the fleet of aerial vehicles. The vehicle components 425 can be associated with one or more component states 430 and/or component models 435.

A respective vehicle model 410 can be indicative of one or more vehicle attributes of an aerial vehicle. The vehicle attributes for a respective aerial vehicle can identify a state (e.g., location, power level, etc.) of the vehicle at one or more time steps of the operational time period. As one example, the vehicle attributes for a respective vehicle can include one or more of battery health data (e.g., a current, predicted, etc. power level of the vehicle), vehicle health data (e.g., a state of one or more components of the vehicle), pilot data (e.g., a current, predicted, etc. available time of an operator of the vehicle), usage data 445 (e.g., flight hours, etc.), or location data (e.g., current, predicted, etc. location of the vehicle) associated with the respective vehicle. In some implementations, for example, the vehicle model 410 can be indicative of usage information 445 (e.g., historical usage, current usage, expected usage, etc.) for a respective aerial vehicle. The usage data 445 can be indicative historical, current, and/or expected flight time for the vehicle and/or the operator of the vehicle. In some cases, the current state of an aerial vehicle can be determined based at least in part on the usage data 445.

As another example, the vehicle attributes can include one or more operational capabilities 420, a list of components and/or types of components 425 of the aerial vehicle, and/or a current state 430 and/or health of each of the vehicle components. The vehicle components 425, for example, can include one or more hardware components and/or software components for each of the plurality of aerial vehicles. The hardware components can include at least one power components (e.g., an engine, fuel tank, battery, etc.), climate control components, navigation components, flight control components, etc. The one or more software components can include one or more software applications (e.g., an operating system, a user interface, etc.) associated with the aerial vehicle. The component state 430 of each of the aerial components can identify a health (e.g., a power level, a current software version, etc.) of each of the one or more components 425. For example, the component state 425 of a power component can identify a power level (e.g., fuel level, charge level, etc.) of the power component (e.g., battery, fuel tank, etc.) for a respective aerial vehicle.

In some implementations, the vehicle model 410 can be associated with one or more component models 435. For example, the vehicle model 410 can be associated with a battery model modelling one or more attributes of a battery of the aerial vehicle. For instance, the battery model can be indicative of one or more performance characteristic(s) of an electric battery of a respective aerial vehicle. The performance characteristics can be indicative of an expected long term performance (e.g., life expectancy) of the battery and/or an expected short term performance (e.g., charge level) of the battery. In addition, the performance characteristics can be indicative of maintenance (e.g., slow charge, fast charge, etc.) that can affect the expected long term and/or short term performance of the battery. The battery model can include structural information such as a type of cells used, the chemistry within each of the cells, an organizational structure of the cells, how cell modules are packed together, materials used that may affect the dissipation of heat, etc. In some implementations, the performance characteristics of the electric battery can be determined based, at least in part, on the structural information.

The vehicle provider computing system 140 can determine one or more flight schedule(s) 490 for one or more vehicles of the fleet of aerial vehicles 450. Each flight schedule can include one or more flight itineraries 495 for each vehicle of the fleet of aerial vehicles 450. A flight itinerary 495, for example, can include one or more flight attributes. The one or more flight attributes can include a departure time, a departure location (e.g., the aerial transportation facility, a take-off location of the aerial transportation facility, etc.), a destination time (e.g., estimated time of arrival at a destination facility), a destination location, a vehicle capacity (e.g., number of passengers, etc.), a vehicle operator associated with the aerial transportation leg and/or any other information associated with the provision of an aerial transportation service.

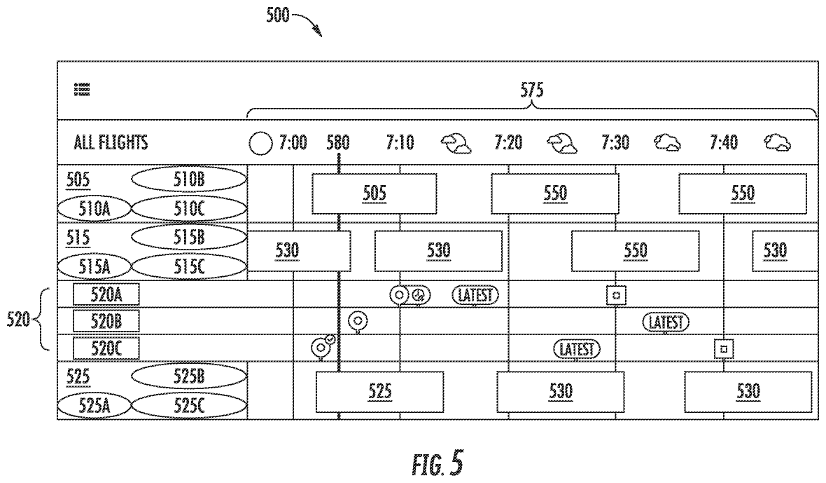

FIG. 5 depicts example operations schedule 500 according to example embodiments of the present disclosure. The operations schedule 500 can include a plurality of flight itineraries 505, 515, 525, 530 and maintenance events 550 throughout an operational time period 575. The plurality of flight itineraries can include one or more current flight itineraries 505, 515, 525 and one or more future itineraries 530. The one or more current flight itineraries 505, 515, 525 can begin (e.g., board), progress (e.g., take-off, fly, land, etc.), and/or end (e.g., deboard) at a current time step 580 of the operational time period 575. The one or more future flight itineraries 530 can begin, progress, and/or end at a future time step subsequent to the current time step 580.

Each flight itinerary 505, 515, 525, 530 can include a plurality of attributes 510A-C, 515A-C, 525A-C. The plurality of attributes 510A-C, 515A-C, 525A-C can include a departure/destination location 510A, a vehicle capacity 510B, and/or a current status 510C (e.g., boarding, taking-off, en-route, landing, deboarding, etc.). In addition, the flight itineraries 505, 515, 525, 530 can include a passenger manifest 520. The passenger manifest 520 can include a list of passengers 520A-C and/or one or more passenger attributes associated with each of the passengers 520A-C. The one or more maintenance events 550 can include a scheduled event for servicing an aerial vehicle. Servicing an aerial vehicle can include refueling, recharging, and/or repairing one or more components of the aerial vehicle.

Turning back to FIG. 1, in scenarios in which the aerial transportation modality operates according to a scheduled itinerary as described with reference to FIG. 4, after identifying relevant fixed transportation nodes associated with a multi-modal transportation service from an origin location to a destination location, the service entity computing system 102 can obtain one or more candidate flight itineraries associated with the multi-modal transportation service (e.g., the origin and/or destination location). The one or more candidate flight itineraries, for example, can include the flight schedules for each relevant fixed transportation node of the multi-modal transportation service. The service entity computing system 102 can obtain the one or more candidate flight itineraries to identify candidate transportation plans between the relevant nodes. In some implementations, for example, the vehicle provider computing system 140 can provide a flight schedule for each of the relevant nodes to the service entity computing system 102. The service entity computing system 102 can be configured to generate one or more multi-modal transportation itineraries based, at least in part, on the flight schedules and multi-modal transportation data. For example, the service entity computing system 102 can identify any transportation plans between one of the candidate departure nodes and one of the candidate arrival nodes which would satisfy the rider's request, including, for example, any departure or arrival time requests.

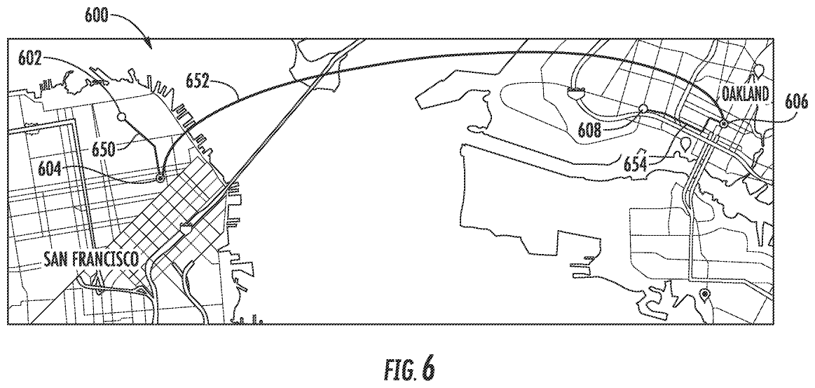

By way of example, FIG. 6 depicts a graphical diagram of an example multi-modal transportation service itinerary 600 according to example embodiments of the present disclosure. The multi-modal transportation itinerary 600 can include three transportation legs to transport the rider from an origin 602 to a destination 608. In particular, the multi-modal transportation itinerary 600 can include a first, ground-based (e.g., car-based) transportation leg 650 which transports the rider from the origin 602 to a departure transportation node 604; a second, flight-based transportation leg 652 which transports the rider from the departure transportation node 604 to an arrival transportation node 606; and a third, ground-based (e.g., car-based) transportation leg 654 which transports the rider from the arrival transportation node 606 to the destination 608. More particularly, the multi-modal transportation itinerary 600 can include a first ground transportation leg 650 from the origin location 602 to a first aerial transportation facility 604, an aerial transportation leg 652 from the first aerial transportation facility 604 to a second aerial transportation facility 606, and a second ground transportation leg 654 from the second aerial transportation facility 606 to the destination location 608. The aerial transportation leg 652 can include a selected plan (e.g., flight itinerary) of one or more candidate flight itineraries obtained from the vehicle provider computing system.

The service entity computing system 102 can utilize the plurality of service provider and/or service entity aerial vehicles for facilitating aerial transportation services for a number of riders based on the one or more flight schedules (e.g., flight schedules 490 of FIG. 4). To do so, the service entity computing system 102 can receive multi-modal transportation data indicative of one or more requests for a plurality transportation services and generate a plurality of multi-modal transportation itineraries for facilitating the plurality of transportation services. An aerial vehicle can be assigned (e.g., by the service provider computing system 102, the vehicle provider computing system 140, etc.) to provide at least one leg of the multi-modal transportation itinerary based on a flight itinerary generated by the service entity computing system 102 and/or obtained from the vehicle provider computing system 140. For example, the multi-modal transportation itinerary can include at least one aerial transportation leg. The aerial vehicle can be assigned to provide the at least one aerial transportation leg.

In some implementations, the aerial transportation leg can be selected from a ranked list of simulated aerial flight itineraries. For example, the simulation system 138 can generate a plurality of simulated flight itineraries and simulate a plurality of aerial transportation services associated with the plurality of simulated flight itineraries. The plurality of simulated flight itineraries can be ranked according to one or more cost functions. At a respective timestep of a respective operational time period, the computing system(s) 102, 140 (e.g., via user input, one or more rules-based techniques, etc.) can receive a ranked list of simulated flight itineraries for the time step and select a simulated flight itinerary from the ranked list of simulated flight itineraries. The computing system(s) 102, 140 can initiate a real aerial transportation service based on the selected simulated flight itinerary and obtain operational data indicative of the performed flight itinerary.

More particularly, to help optimize multi-modal transportation services provided throughout an operational time period, the simulation system 138 can generate and initiate a number of simulation instances for each time step of an operational time period. The operational time period, for example, can include any unit of time during which transportation services can be provided. By way of example, the operational time period can include one or more hours, days, weeks, etc. of operations. The simulation instances can be utilized by the service entity computing system 102 and/or provided to the vehicle provider computing system 140 to facilitate the scheduling, fulfillment, and/or modification of transportation services during the operational time period.

The simulation system 138 can generate a plurality of simulation instances based on real-world conditions. Each simulation instance can include a simulated flight itinerary (and/or a simulated end-to-end multi-modal transportation itinerary including the simulated flight itinerary as at least one leg) performed in a simulated world environment representing one or more constraints (e.g., demand constraints, vehicle constraints, weather constraints, etc.) of the real world at a respective time step. For example, the simulated world environment at a current time step can represent the current state of the real world as maintained by the world state system 126. The simulated world environment at a respective time step subsequent to the current time step can represent a predicted state of the real world as determined by the forecasting system 128.

For example, simulation data can be generated by the simulation system 138 based on multi-modal transportation data, candidate itinerary data, and/or vehicle data. The simulation data can be indicative of a simulated flight itinerary. The simulated flight itinerary can be indicative of an expected performance of an aerial transportation service. In some implementations, the simulation data can include data indicative of a plurality of simulated flight itineraries for one or more operational time periods. The plurality of simulated flight itineraries can include one or more simulated flight itineraries previously generated for one or more time steps of each of the one or more operational time periods. As an example, the simulation data can be indicative of a plurality of simulated flight itineraries, each respective simulated flight itinerary of the plurality of simulated flight itineraries generated before a performance of a corresponding aerial transportation service at a respective time step of a respective operational time period. The respective simulated flight itinerary can be determined based, at least in part, on one or more operational constraints for the respective time step.

By way of example, each simulated flight itinerary can include a flight itinerary performed within a simulated world environment representing one or more expected conditions of the real world at a respective time step. The simulated world environment can be generated based on one or more operational constraints representing one or more real world attributes. The operational constraint(s) can be utilized to model the real world at one or more future time steps. The simulation system 138 can determine the expected performance of an aerial transportation service by generating a simulated flight itinerary corresponding to the aerial transportation service and simulating the corresponding aerial transportation service within the simulated world environment.

Each simulated flight itinerary can be indicative of the expected performance of a respective aerial transportation service. By way of example, the expected performance of the aerial transportation service can include a plurality of expected performance parameters. The expected performance parameters, for example, can include an expected start time (e.g., boarding time, take-off time, etc.), an expected end time (e.g., landing time, deboarding time, etc.), an expected flight duration, an expected passenger capacity (e.g., number of passengers for a flight, seat assignments for the passengers, etc.), an expected weight distribution, an expected start location (e.g., origin aerial facility, take-off location, etc.), an expected route, and/or an expected destination location (e.g., destination aerial facility, landing pad, parking location, etc.).

The simulation data can be generated based on real time and predicted demand, supply, weather, and/or any other factor that can affect transportation services throughout an operational time period. The simulation system 138 can simulate the plurality of flight itineraries for each time step throughout one or more operational time periods. For instance, at each respective time step, the simulation system 138 can generate a plurality of flight itineraries based on real-time data (e.g., received from the world state system 126) up to the time step preceding the respective time step and/or prediction data (e.g., received from the forecasting system 128) for one or more time steps subsequent to the respective time step.

More particularly, the simulation system 138 can generate the plurality of simulated itineraries based on operational constraints. The operational constraints can include at least one of one or more demand constraints, multi-modal itinerary constraints, vehicle constraints (e.g., the vehicle model 410 of FIG. 4), and/or one or more environmental constraints. For example, the simulation system 138 can include and/or have access to one or more models (e.g., vehicle model, network model, candidate models, optimization model, etc.) configured to determine the one or more operational constraints. Each of the models can determine one or more constraints based on real time data. The real time data can be indicative of at least one of a number of requests for aerial transport services, one or more scheduled flight itineraries, vehicle data, and/or environment data at and/or up to a respective time step. The environmental data, for example, can be indicative of one or more environmental conditions at and/or up to the respective time step.

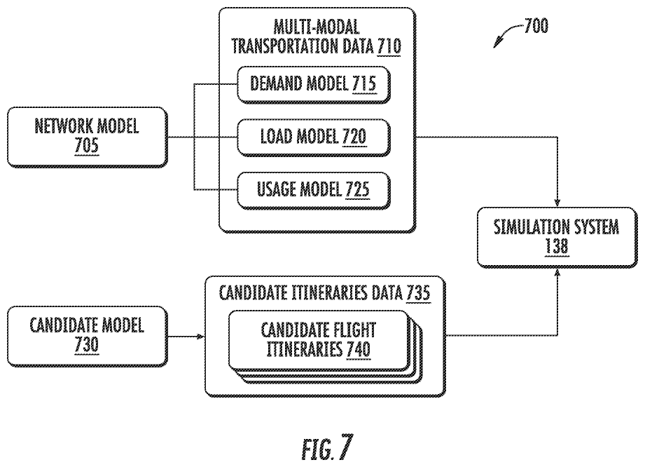

For example, FIG. 7 depicts a data flow diagram 700 for generating example operational constraints according to example embodiments of the present disclosure. The operational constraints can include multi-modal transportation data 710, candidate itinerary data 735, and/or one or more additional constraints (e.g., environmental constraints, vehicle constraints, etc.) described herein.

As an example, the multi-modal transportation data 710 can be indicative of one or more anticipated, real-time, and/or scheduled requests for an aerial transportation service. The one or more requests can include one or more real-time requests received at a respective time step, one or more scheduled requests received at a time step preceding the respective time step and assigned to a scheduled multi-modal transportation itinerary (e.g., including a scheduled flight itinerary), and/or one or more anticipated requests for one or more time steps subsequent to the respective time step. The one or more anticipated requests can include an estimated number of requests that will be received at one or more time steps throughout an operational time period. For example, the multi-modal transportation data 710 can include demand data indicative of a plurality of anticipated requests and/or one or more aspects thereof. For instance, the demand data can be indicative of the one or more anticipated transportation services throughout one or more operational time periods.

The multi-modal transportation data 710 can include a comprehensive overview of a number of services that can be fulfilled throughout an operational time period and/or one or more attributes of those services. For example, the multi-modal transportation data 710 can identify one or more types of services (e.g., time sensitive, capacity sensitive, etc.), one or more aerial transportation facilities associated with each of the services, a number of services that can be fulfilled for each transportation facility, etc. In some implementations, the multi-modal transportation data 710 can include itinerary data. The itinerary data can include one or more multi-modal transportation itineraries for the one or more scheduled and/or anticipated aerial transportation services.

As another example, the one or more operational constraints can include candidate itinerary data 735 indicative of one or more candidate flight itinerary(s) 740 at one or more time steps throughout one or more operational time periods. The one or more candidate flight itinerary(s) 740 can be determined by the service entity computing system and/or obtained from a vehicle provider computing system. For example, the service entity computing system (e.g., optimization/planning system) can include and/or be associated with a candidate model 730 configured to generate the candidate itinerary constraints. The candidate model 730 can include one or more machine-learned models. The candidate model 730 can be configured to determine a respective plurality of candidate flight itineraries 740 for one or more time steps throughout the one or more operational time periods. For example, the candidate flight itineraries 740 can include every possible flight plan between each of a number of aerial facilities at a respective time step.

The multi-modal transportation data 710 can be determined by a network model 705 and/or one or more sub models (e.g., demand model 715, load model 720, usage model 725, etc.) of the network model 705. The candidate itinerary data 735 can include one or more candidate flight itinerary(s) 740 determined by the candidate model 730. For example, the service entity computing system (e.g., the forecasting system, etc.) can include and/or be associated with a network model 705 configured to generate the multi-modal transportation data 710 and/or a portion of the multi-modal transportation data 710. The network model 705 can include one or more machine-learned models. For instance, the network model 705 can include a demand model 715, a load model 720, and/or an aerial transport usage model 725. The demand model 715 can be configured to determine an anticipated demand for aerial transport services at one or more time steps throughout one or more operational time periods. The load model 720 can be configured to estimate the maximum expected load factors at one or more time steps throughout the one or more operational time periods. And, the aerial transport usage model 725 can be configured to estimate an expected number of flights for each aerial transport facility of the fixed transportation infrastructure at one or more time steps throughout the one or more operational time periods.

In some implementations, the network model 705 and/or each of the sub models 715, 720, 725 can include one or more machine-learning models. The machine-learning models can include any machine-learning model (e.g., deep neural networks, convolutional neural networks, recurrent neural networks, recursive neural networks, decision trees, logistic regression models, support vector machines, etc.) and/or any other models configured to generate the demand data based on one or more inputs. In some implementations, the one or more machine-learning models can be learned (e.g., via one or more supervised training techniques) over a set a training data such as, for example, historical multi-modal transportation service data (and/or single mode transportation service data) gathered over one or more previous operational time periods.

In some implementations, each of the models 705, 715, 720, 725, 730 can be configured to interact with a computing system (e.g., vehicle provider computing system and/or service entity computing system) to make each respective prediction. For example, a vehicle provider computing system can provide vehicle data and/or any other data available to the vehicle provider computing system to one or more of the models 705, 715, 720, 725, 730. The models 705, 715, 720, 725, 730 can generate the predictions and provide the resulting multi-modal transportation data 710 to the simulation system 138 and/or the vehicle provider computing system for use in developing one or more flight itineraries.

At times, the one or more models 705, 715, 720, 725, 730 and/or other models, services, and/or functions described herein can provide prediction data for a future time step that deviates from data recorded at the future time. Thus, over time, one or more corrective actions can be generated to ensure the accuracy of the one or more models 705, 715, 720, 725, 730 and/or other models, services, and/or functions described herein.

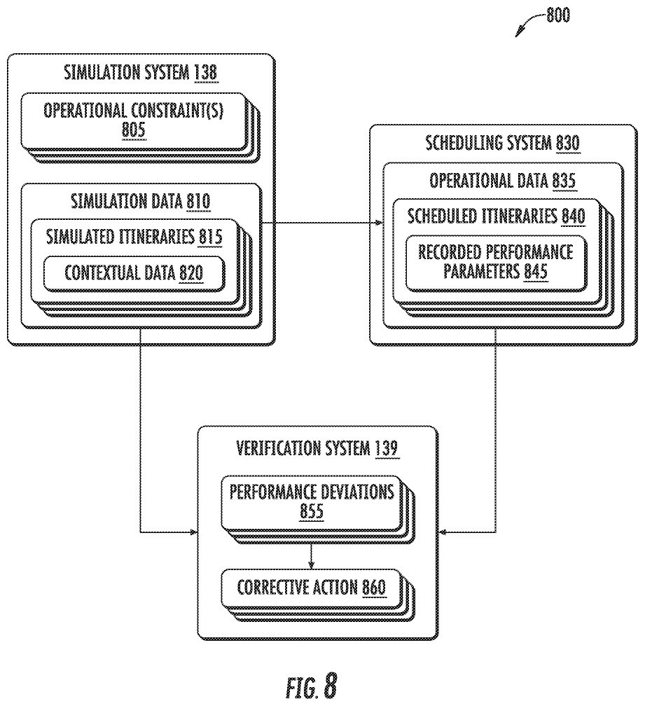

FIG. 8, for example, depicts a data flow diagram 800 for generating corrective actions according to example embodiments of the present disclosure. As illustrated, the simulation system 138 can generate simulation data 810 based on operational constraint(s) 805. The operational constraint(s) 805 can include the operational constraints disclosed herein (e.g., multi-modal transportation data 710, candidate itinerary data 735, etc. with reference to FIG. 7). In addition, or alternatively, the one or more operational constraint(s) 805 can include vehicle constraints and/or one or more environmental constraints. The vehicle constraints can be based on the one or more vehicle models (e.g., vehicle model 410 of FIG. 4) associated with a plurality of aerial vehicles of a respective fleet of vehicles. For instance, the vehicle constraints can include the one or more vehicle operational constraints associated with one or more vehicles. In addition, or alternately, the vehicle constraints can include an availability constraint indicative of an availability of one or more of the plurality of vehicles at a respective time step. In some implementations, the vehicle constraints can include a current state of the one or more available vehicles and/or components thereof. The environmental constraints can be based on one or more weather models (e.g., of the forecasting system 128 of FIG. 1) configured to predict one or more environmental conditions for each time step of each of the one or more operational time periods.

By way of example, a simulated flight itinerary can include a simulation of the performance, preparation, and conclusion of a flight within the simulated world environment. For example, the simulation system 138 can simulate the use of an aerial transportation facility for maintenance, boarding, charging, and/or any other pre-flight tasks for preparing an aerial vehicle to perform the simulated flight itinerary. As an example, the simulated system 138 can obtain pre-flight operational constraints 805 indicative of multi-modal transportation data (e.g., a demand) for a flight departing at a respective time step. The simulation system 138 can schedule the simulated flight itinerary and assign one or more simulated passengers to the simulated flight itinerary based on the multi-modal transportation data. In addition, the pre-flight operational constraints 805 can include vehicle data indicative of the current and/or expected state (e.g., charge level, capacity, etc.) of one or more vehicles at the respective time step. The simulation system 138 can assign an aerial vehicle to perform the simulated flight itinerary and/or one or more pre-flight tasks (e.g., maintenance, charging, fueling, etc.).

The simulation system 138 can obtain additional pre-flight operational constraints 805 such as, for example, current/predicted weather, current/predicted traffic, availability of infrastructure equipment (e.g., charging/maintenance equipment), other scheduled itineraries, etc. to simulate the one or more pre-flight tasks. For example, the simulation system 138 can simulate one or more delayed passengers based on traffic at the respective time step, one or more delayed fueling/charging tasks due to an unavailability of fueling/charging equipment at the respective time step, a delayed take-off due to unavailable landing pads, etc. In like manner, the simulation system 138, using the pre-flight operational constraints 805, can simulate the effect of the simulated flight itinerary on one or more other scheduled and/or simulated itineraries. For example, the simulation system 138 can simulate one or more delayed fueling/charging tasks due to an unavailability of fueling/charging equipment at the respective time step caused by the simulated flight itinerary, a delayed take-off and/or landing of another flight due to unavailable landing pads caused by the simulated flight itinerary, etc.

The simulation system 138 can simulate the performance of a flight based on the simulated flight itinerary. For example, the simulation system 138 can obtain flight operational constraints 805 such as, for example, weather, sky lane congestion, air traffic control, etc. Based on the flight operational constraints 805, the simulation system 138 can simulate the performance of the flight. For example, the simulation system 138 can simulate a flight delay, turbulence, etc. based on weather, a noise level based on the aerial vehicle and/or route, etc. In addition, the simulation system 138 can simulate the use of an aerial transportation facility for landing, maintenance, de-boarding, charging, and/or any other post-flight tasks after the performance of the simulated flight itinerary. As an example, the simulated system 138 can obtain post-flight operational constraints 805 indicative of multi-modal transportation data (e.g., a demand) for a flights departing/landing at an estimated landing time step, vehicle data indicative of the current and/or expected state (e.g., charge level, capacity, etc.) of the vehicle at the time step, current/predicted weather, current/predicted traffic, availability of infrastructure equipment (e.g., charging/maintenance equipment), other scheduled itineraries, etc. to simulate the one or more post-flight tasks.

The simulation data 810 can include a plurality of simulated itineraries 815 for each respective operational time period. The simulated itineraries 815 can be optimized in view of the respective operational time period. The simulation system 138 can generate a ranked list of simulated flight itineraries for a respective time step of a respective operational time period based on a plurality of simulated flight itineraries 815 generated for the respective time step. To do so, the simulation system 138 can determine contextual data 820 for each of a plurality of simulated flight itineraries 815 generated for the respective time step. The contextual data 820 can be indicative of a relative impact of a respective simulated flight itinerary to one or more metrics associated with the operational time period. The one or more metrics, for example, can include an overall noise level, an overall profit margin, an overall ride quality and/or any other measurement observed throughout an operational time period.

The relative impact of the respective simulated flight itinerary can be determined based, at least in part, on a plurality of subsequent simulated flight itineraries generated for one or more time steps subsequent to the respective time step. The plurality of subsequent simulated flight itineraries can be generated based, at least in part, on the respective simulated flight itinerary, and one or more operational constraint(s) 805 (e.g., an anticipated demand, a plurality of candidate flight itineraries, etc.) for the one or more time steps subsequent to the respective time step.

The simulation system 138 can generate a ranked list of flight itineraries based, at least in part, on the contextual data 820 for each of the plurality of simulated flight itineraries 815. Each simulated flight itinerary of the ranked list of flight itineraries can be ranked based, at least in part, on a relative impact of the simulated flight itinerary to one or more of the metrics for the operational time period. As an example, the simulated flight itineraries can be ranked according to a cost function configured to minimize a predicted overall noise level, maximize a predicted profit margin and/or maximize a predicted overall ride quality for the plurality of flight itineraries 815 scheduled during the operational time period.

The ranked list simulated flight itineraries (e.g., simulation data 810) can be provided to a scheduling system 830 for use in generating a flight itinerary and/or a multi-modal transportation itinerary based on a flight itinerary. The scheduling system 830, for example, can interact with the simulation system 138 to determine one or more scheduled itineraries 840. The one or more scheduled itineraries 840 can include one or more multi-modal transportation itineraries and/or one or more transportation legs (e.g., an aerial transportation leg) of a multi-modal transportation itinerary.

The scheduling system 830 can include the service entity computing system 102 and/or the vehicle provider computing system 140 of FIG. 1. For example, the scheduled itineraries 840 can include one or more flight itineraries and service entity computing system 102 can generate one or more multi-modal transportation itineraries based on the one or more scheduled itineraries 840. The one or more scheduled itineraries 840 can be generated by the service entity computing system 102 and/or provided by the vehicle provider computing system 140. In the event that the one or more scheduled itineraries 840 are provided by the vehicle provider computing system 140, the service entity computing system 102 (e.g., simulation system 138, etc.) can provide data such as, for example, simulation data 810 and/or any other data described herein to the vehicle provider computing system 140. The vehicle provider computing system 140 can leverage the data provided by the service entity computing system 102 to generate the scheduled itineraries 840 as described herein.

For instance, the scheduling system 830 can obtain the simulation data 810 and select a simulated flight itinerary from the ranked list of flight itineraries to facilitate an aerial transportation service for a rider. For example, the scheduling system 830 can obtain the ranked list of flight itineraries for a respective time step associated with a request for the aerial transportation service. In some implementations, the ranked list of flight itineraries can be provided for display (e.g., to one or more operators associated with the scheduling computing system 830). In addition, or alternatively, one or more portions of the contextual data 820 associated with each of the simulated flight itineraries 815 of the ranked list of simulated flight itineraries can be provided for display.

The scheduling system 830 can select a flight itinerary for a transportation leg of the multi-modal transportation itinerary associated with the aerial transportation of the rider from the ranked list of flight itineraries. The selection of the selected flight itinerary can be performed automatically by the scheduling system 830 (e.g., via a selection algorithm (e.g., based on rank and/or one or more other portions of the contextual data 820)) and/or by an operator of the scheduling system 830 (e.g., via user input). For example, the selection algorithm can include an automatic selection logic that selects a simulated flight itinerary based on one or more attributes (e.g., highest ranked itinerary, lowest ranked itinerary, etc.) of the contextual data 820 accompanying the ranked list of simulated flight itineraries. In addition, or alternatively, the scheduling system 830 can receive user input indicative of a selection of the selected flight itinerary. The user input can be received via one or more input devices (e.g., microphone, tactile device (e.g., keyboard, mouse, button, etc.), etc.) of the scheduling system 830 and/or via one or more devices (e.g., rider devices, operator device, etc.) communicatively connected to the scheduling system 830.

The scheduling system 830 can initiate the performance of an aerial transportation service based on a selected itinerary. The scheduling system 830 can track the performance of the aerial transportation service and record operational data 835 including a plurality of recorded performance parameters 845 for the scheduled itinerary 840. The plurality of performance parameters 845 can include at least one of an actual start time, an actual end time, an actual flight duration, an actual passenger capacity, an actual weight distribution, an actual start location, an actual route, and/or an actual destination location. In this manner, the scheduling system 830 can obtain data indicative of a performed flight itinerary (e.g., the scheduled itinerary 840). The performed flight itinerary can be indicative of the recorded performance of an aerial transportation service corresponding to a selected simulated flight itinerary. For example, each respective performed flight itinerary can correspond to the corresponding aerial transportation service at a respective time step of the respective operational time period.

The verification system 139 can analyze the simulation data 810 generated over a number of operational time periods and operational data 835 recorded over a number of operational time periods to identify one or more performance deviations 855 between the simulation data 810 and the operational data 835. For example, the verification system 139 can obtain the simulation data 810 indicative of a simulated flight itinerary and the operational data 835 indicative of a performed flight itinerary (e.g., a scheduled itinerary 840). The simulation data 810 can be indicative of a plurality of simulated flight itineraries 815 for one or more operational time periods. The operational data 835 can be indicative of a plurality of performed flight itineraries 840 during the one or more operational time periods.

The plurality of simulated flight itineraries 815 can include one or more selected itineraries, one or more provided itineraries, and/or one or more discarded itineraries. For example, the one or more provided itineraries can include a plurality of ranked lists of simulated flight itineraries for one or more time steps throughout one or more operational time periods. The one or more discarded itineraries can include one or more simulated flight itineraries that were generated but discarded (e.g., due to a low rank, etc.) and not included in a respective ranked list of simulated flight itineraries. As discussed herein, each ranked list of simulated flight itineraries can be ranked according to one or more cost functions and each respective ranked list of simulated flight itineraries can include contextual data 820 for each respective simulated flight itinerary of the respective ranked list. In some implementations, each respective selected itinerary of the one or more selected itineraries can be selected from a respective ranked list of simulated flight itineraries. The operational data 835 can be indicative of a plurality of scheduled and performed flight itineraries 840 including a respective scheduled/performed flight itinerary for each of the one or more selected itineraries.

The verification system 139 can determine one or more performance deviations 855 associated with a simulated flight itinerary based, at least in part, on the simulation data 810 and the operational data 835. For example, the verification system 139 can determine the performance deviations 855 based on the recorded performance of an aerial transportation service corresponding to the simulated flight itinerary. By way of example, the recorded performance can include data indicative of the performance of an actual aerial transportation service in the real world that was selected/scheduled based on the previously simulated performance of a simulated flight itinerary performed in a simulated world. The performance deviations 855 are indicative of one or more differences between the plurality of recorded performance parameters 845 and the plurality of expected performance parameters of the simulated itineraries 815. By way of example, a performance deviation can include one or more time differences (e.g., the simulated boarding, take-off, landing, de-boarding, etc. time is later/earlier than a recorded counterpart), one or more vehicle state differences (e.g., the simulated vehicle state such as a predicted power level at one or more time points is higher/lower than a recorded power level, etc. at the respective one or more time points), and/or any other deviation from a simulated/expected performance of a transportation service.

For example, a simulated flight itinerary can include a first set of expected performance parameters indicative of an estimated time of arrival at a first time step, a power expenditure of a respective percentage, etc. The first set of expected performance parameters can reflect the result of the performance of the simulated flight itinerary in the simulated world environment. The actually performed flight itinerary can include a second set of parameters different than the first set of parameters. For example, second set of recorded parameters can have a time of arrival at a second time step, a power expenditure of a different percentage, etc. The second set of recorded performance parameters can reflect the result of the performance of the flight itinerary in the real world.

The verification system 139 can generate one or more corrective actions 860 based, at least in part, on the one or more performance deviations 855. The corrective action(s) 860 can be associated with at least one of a generation of the simulated flight itinerary and/or a selection of the simulated flight itinerary. For example, the corrective action(s) 860 can include a modification to one or more of the operational constraint(s) 805 (and/or the determination thereof) utilized by the simulation system 138 to generate the simulated flight itineraries 815. As an example, the modification can include a modification to one or more of the models (e.g., vehicle models, network models, demand models, load models, usage models, candidate models, etc.) configured to generate one or more of the operational constraints 805. In addition, or alternatively, the corrective action(s) 860 can include a modification to one or more cost functions utilized to rank the simulated flight itineraries 815, an order in which to rank the simulated flight itineraries 815, portions of contextual data 820 that are provided with the simulated flight itineraries 815, and/or any other aspect associated with selecting a simulated flight itinerary for facilitating a multi-modal transportation itinerary.

For example, to generate a corrective action 860, the verification system 139 can identify a shared performance deviation associated with one or more of the plurality of simulated flight itineraries 815 based, at least in part, on the operational data 835. A shared performance deviation can include a common performance deviation across a plurality of simulated flight itineraries. Each performance deviation can be indicative of an expected performance parameter that is consistently different than a recorded performance parameter for a plurality of simulated/scheduled flight itineraries 815, 840. By way of example, the shared performance deviation can include a plurality of simulated times (e.g., estimated arrival time, etc.), weight distributions, passengers, routes, etc. across a plurality of simulated itineraries that are consistently different than a recorded time, weight distribution, passengers, routes, etc. for scheduled flights based on the simulated flight itineraries. For instance, a shared performance deviation can identify a plurality of simulated flight itineraries with estimated times of arrival that deviate from a plurality of recorded times of arrival for a plurality of scheduled flight itineraries corresponding to the simulated flight itineraries.

The verification system 139 can determine one or more correlating parameters of the one or more simulated flight itineraries associated with the shared performance deviation. The correlating parameter(s) can include one or more performance parameters (e.g., expected, recorded, etc.) and/or operational constraints associated with each of the one or more simulated flight itineraries. By way of example, the correlating parameter(s) can include one or more expected and/or recorded parameters (e.g., time, weight distribution, passengers, routes, etc.) shared by each of the simulated flight itineraries associated with the shared performance deviation. In addition, the correlating parameter(s) can include one or more operational constraints shared by each of the simulated flight itineraries associated with the shared performance deviation. By way of example, the one or more shared operational constraints can include a demand constraint, multi-modal itinerary constraint, vehicle constraint (e.g., a vehicle model), environmental constraint, etc. that are used to generate each of the simulated flight itineraries.

The verification system 139 can generate a corrective action 860 for the shared performance deviation based, at least in part, on the one or more correlating parameters. By way of example, a correlating parameter can include an operational constraint (e.g., one or more operational constraints 805). In addition, or alternatively, the correlating parameter can include a shared performance parameter indicative of an operational constraint (e.g., a flight time can be indicative of a vehicle model, etc.). In such a case, the corrective action 860 for the shared performance deviation can be indicative of a modification to the determination of the operational constraint (e.g., by modifying one or more parameters of a model/function associated with the operational constraint).

As an example, the operational constraint can be a vehicle constraint determined based, at least in part, on a vehicle model indicative of a plurality of vehicle attributes. In such a case, the modification to the determination of the vehicle constraint can include a modification to at least one of the plurality of vehicle attributes (e.g., to lower the speed, passenger capacity, rating, charge rate, power consumption, etc. of respective vehicle). As another example, at least one of the one or more correlating parameters can be indicative of an aerial vehicle provider. In such a case, the corrective action 860 for the shared performance deviation can include associating the shared performance deviation with the aerial vehicle provider. This can include, for example, modifying one or more parameters of a vehicle model associated with the aerial vehicle provider, etc.

In addition, or alternatively, the verification system 139 can generate a corrective action 860 indicative of a change to the ranking of future simulated flight itineraries and/or the contextual data 820 associated therewith. For example, the corrective action 860 can include a modification to at least one of the one or more cost functions utilized to rank the simulated flight itineraries. The modification, for example, can modify one or more parameters of the cost function(s) to prioritize one or more different metrics associated with an operational time period. By way of example, the verification system 139 can determine, based on the one or more performance deviations 855, that an optimal simulated flight itinerary is consistently ignored (e.g., an optimal flight itinerary is discarded based on a low ranking, or provided but ignored by the selecting operator and/or system). In such a case, the verification system 139 can determine one or more corrective actions 860 to alter the rankings of future simulated flight itineraries to reduce the chances that the optimal simulated flight itinerary is ignored.

As another example, the verification system 139 can generate a corrective action indicative of a change to the contextual data 820 and/or portions thereof that are provided with each simulated flight itinerary of a ranked list of simulated flight itineraries. For instance, contextual data 820 can be determined for each respective simulated flight itinerary based, at least in part, on one or more selection criteria. The selection criteria can prioritize one or more portions of the contextual data 820 (e.g., an estimated noise level, etc.). The verification system 139 can determine that one or more different portions of contextual data 820 are more desirable and/or can lead to the selection of a more optimal itinerary. In such a case, the corrective action 860 can include a modification to the one or more selection criteria and, thus, the one or more portions of contextual data 820 provided with each simulated flight itinerary 815.

In some implementations, the verification system 139 can obtain feedback data associated with the selection of a simulated flight itinerary. The feedback data can include user input or metadata (e.g., number of clicks, time before selection, etc.) associated with the user input. The verification system 139 can generate the one or more corrective actions based, at least in part, on the feedback data. For example, the verification system 139 can determine one or more portions of contextual data 820 and/or a ranking that aid in the selection of an optimal simulated itinerary based, at least in part on the feedback data.

The verification system 139 can output the one or more corrective actions 860 to a user and/or one or more system(s) 138, 830 (e.g., world state system, forecasting system, optimization/planning system, vehicle provider system, etc.) associated with the generation and/or selection of multi-modal transportation itineraries. For example, the one or more corrective actions 860 can include recommendations to make one or more modifications to one or more models, functions, services, etc. provided by the one or more systems. A respective system 138, 830 (and/or user thereof) can obtain the recommendations and determine whether to implement the modification by modifying one or more parameters of a corresponding model, function, service, etc.

In some implementations, the verification system 139 can provide data indicative of the one or more corrective actions 860 to the respective system(s) 138, 830. The data can be indicative of at least one modification to the generation of a simulated flight itinerary or a selection of a simulated flight itinerary and/or a predicted impact of the at least one modification (e.g., a predicted reduction of the performance deviation, etc.). As an example, the data indicative of the one or more corrective actions 860 can include a recommended modification, an object (e.g., model, function, service, etc.) associated with the modification, and/or the predicted impact of the modification. The respective system(s) 138, 830 (and/or user thereof) can obtain the data indicative of the one or more corrective actions 860 and determine whether to implement the associated recommended modifications based on the predicted impact of the recommended modifications. For example, the respective system(s) 138, 830 can automatically determine whether to implement a modification based, at least in part, on a threshold impact. In the event that the predicted impact achieves the threshold impact, the respective system(s) 138, 830 can be configured to implement the modification. The respective system(s) 138, 830 can implement a modification by modifying the object (e.g., one or more parameters of a model, function, service, etc.) associated with the corrective action 860.

As another example, the one or more corrective actions 860 can be provided for display, via one or more display devices, to a user of a respective system(s) 138, 830. By way of example, the verification system 139 can provide for display, via the one or more display devices, data indicative of the one or more corrective actions 860. The user of the respective system(s) 138, 830 can select at least one of the one or more corrective actions 860. In response, the respective system(s) 138, 830 can implement the modification associated with the selected corrective action 860.

By way of example, the data indicative of a corrective action can include a recommended modification to a demand model. The modification can include retraining the demand model based on updated historical demand data and the predicted impact of the modification can include more accurate predictions of predicted demand. The corrective action can be determined by the verification system 139 based on one or more performance deviations and/or correlating parameters indicative of the demand model. For instance, the verification system 139 can determine a performance deviation indicative of a lower number of simulated flight itineraries for a respective time step than the actual number of scheduled flight itineraries for the respective time step. The verification system can review the operational constraints utilized to generate the simulated flight itineraries at the respective time and, based on this review, determine that a correlating parameter associated with the simulated flight itineraries is a predicted demand for the respective time step that is different than the actual demand for the respective time step. In response, the verification system 138 can generate the corrective action indicative of the lower number of simulated flight itineraries, the predicted demand for the number of simulated flight itineraries, and the demand model configured to predict the demand. The data indicative of the corrective action can be provided to a system (e.g., forecasting system 128 of FIG. 1) associated with the demand model and the system can implement the corrective action by relearning the demand model over updated historical demand data. In this manner, models (e.g., machine-learned models, etc.) utilized to generate one or more operational constraints can be selectively updated over time based on the accuracy of the models.

As another example, the data indicative of a corrective action can include a recommended modification to a vehicle model. The modification can include modifying an attribute of the vehicle model and the predicted impact of the modification can include more accurate predictions of vehicle performance. The corrective action can be determined by the verification system 139 based on one or more performance deviations and/or correlating parameters indicative of the vehicle model. For instance, the verification system 139 can determine a performance deviation indicative of a later estimated time of arrival for a plurality of simulated flight itineraries than the actual time of arrival for a plurality of scheduled flight itineraries. The verification system 139 can review the operational constraints utilized to generate the simulated flight itineraries and, based on this review, determine that a correlating parameter associated with the simulated flight itineraries is a vehicle model (e.g., the same vehicle and/or type of vehicle is used for each scheduled itinerary). In response, the verification system 138 can generate the corrective action indicative of the inconsistent time of arrival, the vehicle model utilized to predict the time of arrival, and a modification to a speed attribute (e.g., an average speed of the vehicle) of the vehicle model. The data indicative of the corrective action can be provided to a system (e.g., matching/fulfillment system 132, vehicle provider computing system(s), etc. of FIG. 1) associated with the vehicle model and the system can implement the corrective action by modifying the speed attribute of the vehicle model. In this manner, models (e.g., machine-learned models, etc.) utilized to generate one or more operational constraints can be selectively updated over time based on the accuracy of the models.

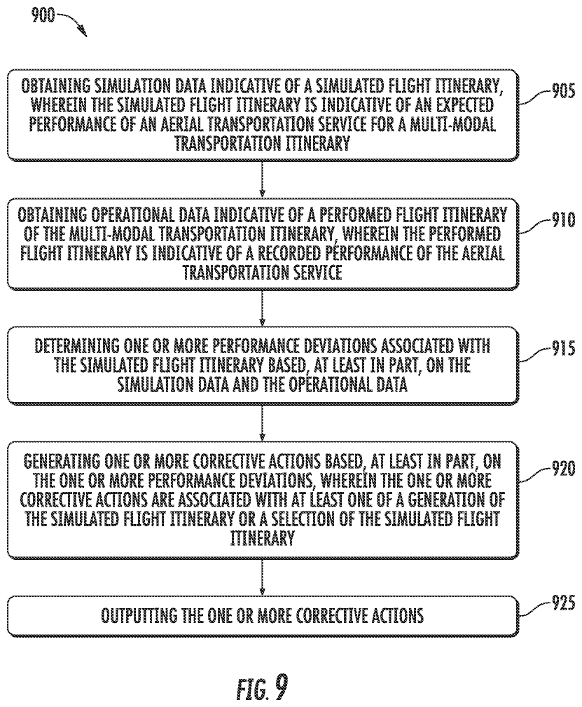

Turning to FIG. 9, FIG. 9 depicts a flow diagram 900 of an example method for generating corrective actions according to example embodiments of the present disclosure. One or more portion(s) of the method 900 can be implemented by a computing system that includes one or more computing devices such as, for example, the computing systems described with reference to the other figures (e.g., system 100, service entity computing system 102, simulation system 138, verification system 139, vehicle provider computing system(s) 140, etc.). Each respective portion of the method 900 can be performed by any (or any combination) of one or more computing devices. Moreover, one or more portion(s) of the method 900 can be implemented as an algorithm on the hardware components of the device(s) described herein (e.g., as in FIGS. 1, 4, 7, 11, etc.), for example, to generate corrective actions. FIG. 9 depicts elements performed in a particular order for purposes of illustration and discussion. Those of ordinary skill in the art, using the disclosures provided herein, will understand that the elements of any of the methods discussed herein can be adapted, rearranged, expanded, omitted, combined, and/or modified in various ways without deviating from the scope of the present disclosure. FIG. 9 is described with reference to elements/terms described with respect to other systems and figures for exemplary illustrated purposes and is not meant to be limiting. One or more portions of method 900 can be performed additionally, or alternatively, by other systems.

At 905, the method 900 can include obtaining simulation data indicative of a simulated flight itinerary. For example, a computing system (e.g., service entity computing system 102, verification system 139, etc.) can obtain simulation data indicative of the simulated flight itinerary. The simulated flight itinerary can be indicative of an expected performance of an aerial transportation service for a multi-modal transportation itinerary.

At 910, the method 900 can include obtaining operational data indicative of a performed flight itinerary of the multi-modal transportation itinerary. For example, the computing system (e.g., service entity computing system 102, verification system 139, etc.) can obtain operational data indicative of the performed flight itinerary of the multi-modal transportation itinerary. The performed flight itinerary can be indicative of a recorded performance of the aerial transportation service.

At 915, the method 900 can include determining one or more performance deviations associated with the simulated flight itinerary based, at least in part, on the simulation data and the operational data. For example, the computing system (e.g., service entity computing system 102, verification system 139, etc.) can determine the one or more performance deviations associated with the simulated flight itinerary based, at least in part, on the simulation data and the operational data.

At 920, the method 900 can include generating one or more corrective actions based, at least in part, on the one or more performance deviations. For example, the computing system (e.g., service entity computing system 102, verification system 139, etc.) can generate the one or more corrective actions based, at least in part, on the one or more performance deviations. The one or more corrective actions can be associated with at least one of a generation of the simulated flight itinerary and/or a selection of the simulated flight itinerary.

At 925, the method 900 can include outputting the one or more corrective actions. For example, the computing system (e.g., service entity computing system 102, verification system 139, etc.) can output the one or more corrective actions to one or more respective systems associated with the corrective action.

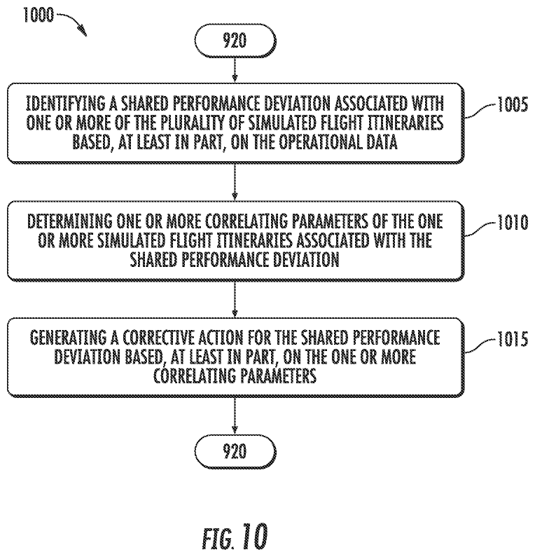

Turning to FIG. 10, FIG. 10 depicts another flow diagram 1000 of an example method for generating corrective actions according to example embodiments of the present disclosure. One or more portion(s) of the method 1000 can be implemented by a computing system that includes one or more computing devices such as, for example, the computing systems described with reference to the other figures (e.g., system 100, service entity computing system 102, verification system 139, vehicle provider computing system(s) 140, etc.). Each respective portion of the method 1000 can be performed by any (or any combination) of one or more computing devices. Moreover, one or more portion(s) of the method 1000 can be implemented as an algorithm on the hardware components of the device(s) described herein (e.g., as in FIGS. 1, 4, 7, 11, etc.), for example, to generate one or more corrective actions. FIG. 10 depicts elements performed in a particular order for purposes of illustration and discussion. Those of ordinary skill in the art, using the disclosures provided herein, will understand that the elements of any of the methods discussed herein can be adapted, rearranged, expanded, omitted, combined, and/or modified in various ways without deviating from the scope of the present disclosure. FIG. 10 is described with reference to elements/terms described with respect to other systems and figures for exemplary illustrated purposes and is not meant to be limiting. One or more portions of method 1000 can be performed additionally, or alternatively, by other systems.

FIG. 10 begins and ends, at 920, of flow diagram 900 where the method includes generating the one or more corrective actions based, at least in part, on the one or more performance deviations.

At 1005, the method 1000 can include determining/identifying a shared performance deviation associated with one or more of a plurality of simulated flight itineraries based, at least in part, on the operational data. For example, a computing system (e.g., service entity computing system 102, verification system 139, vehicle provider computing system 140, etc.) can determine/identify a shared performance deviation associated with the one or more of the plurality of simulated flight itineraries based, at least in part, on the operational data.

At 1010, the method 1000 can include determining one or more correlating parameters of the one or more simulated flight itineraries associated with the shared performance deviation. For example, the computing system (e.g., service entity computing system 102, verification system 139, vehicle provider computing system 140, etc.) can determine one or more correlating parameters of the one or more simulated flight itineraries associated with the shared performance deviation.

At 1015, the method 1000 can include generating a corrective action for the shared performance deviation based, at least in part, on the one or more correlating parameters. For example, the computing system (e.g., service entity computing system 102, verification system 139, vehicle provider computing system 140, etc.) can generate the corrective action for the shared performance deviation based, at least in part, on the one or more correlating parameters.

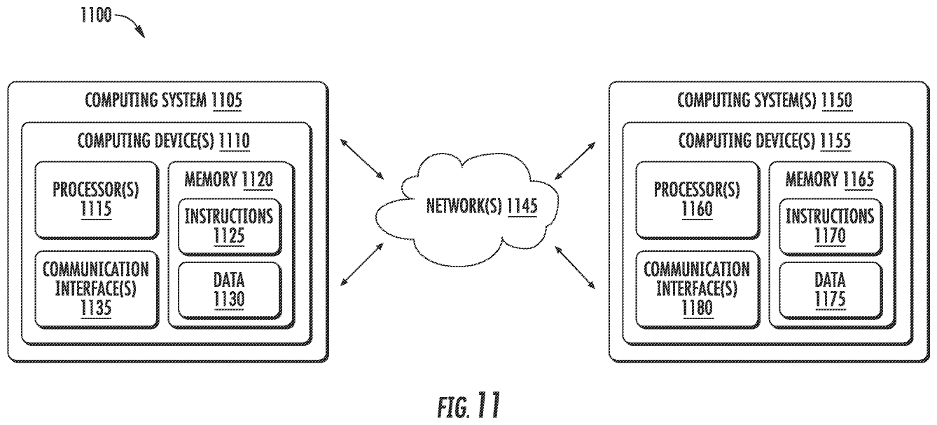

FIG. 11 depicts example system components of an example system 1100 according to example embodiments of the present disclosure. The example system 1100 can include the computing system 1105 (e.g., service entity computing system 102, verification system 139, etc.) and the computing system(s) 1150 (e.g., vehicle provider computing system(s) 140, rider computing device(s) 145, service provider computing device(s) 150, 160, 170, infrastructure and operations computing device(s) 190, etc.), etc. that are communicatively coupled over one or more network(s) 1145.

The computing system 1105 can include one or more computing device(s) 1110. The computing device(s) 1110 of the computing system 1105 can include processor(s) 1115 and a memory 1120. The one or more processors 1115 can be any suitable processing device (e.g., a processor core, a microprocessor, an ASIC, a FPGA, a controller, a microcontroller, etc.) and can be one processor or a plurality of processors that are operatively connected. The memory 1120 can include one or more non-transitory computer-readable storage media, such as RAM, ROM, EEPROM, EPROM, one or more memory devices, flash memory devices, etc., and combinations thereof.

The memory 1120 can store information that can be accessed by the one or more processors 1115. For instance, the memory 1120 (e.g., one or more non-transitory computer-readable storage mediums, memory devices) can include computer-readable instructions 1125 that can be executed by the one or more processors 1115. The instructions 1125 can be software written in any suitable programming language or can be implemented in hardware. Additionally, or alternatively, the instructions 1125 can be executed in logically and/or virtually separate threads on processor(s) 1115.

For example, the memory 1120 can store instructions 1125 that when executed by the one or more processors 1115 cause the one or more processors 1115 to perform operations such as any of the operations and functions for which the computing system is configured, as described herein.

The memory 1120 can store data 1130 that can be obtained, received, accessed, written, manipulated, created, and/or stored. The data 1130 can include, for instance, simulation data, multi-modal transportation services data, corrective action data, and/or other data/information described herein. In some implementations, the computing device(s) 1110 can obtain from and/or store data in one or more memory device(s) that are remote from the computing system 1105 such as one or more memory devices of the computing system 1150.

The computing device(s) 1110 can also include a communication interface 1135 used to communicate with one or more other system(s) (e.g., computing system 1150). The communication interface 1135 can include any circuits, components, software, etc. for communicating via one or more networks (e.g., 1145). In some implementations, the communication interface 1135 can include for example, one or more of a communications controller, receiver, transceiver, transmitter, port, conductors, software and/or hardware for communicating data/information.

The computing system 1150 can include one or more computing devices 1155. The one or more computing devices 1155 can include one or more processors 1160 and a memory 1165. The one or more processors 1160 can be any suitable processing device (e.g., a processor core, a microprocessor, an ASIC, a FPGA, a controller, a microcontroller, etc.) and can be one processor or a plurality of processors that are operatively connected. The memory 1165 can include one or more non-transitory computer-readable storage media, such as RAM, ROM, EEPROM, EPROM, one or more memory devices, flash memory devices, etc., and combinations thereof.

The memory 1165 can store information that can be accessed by the one or more processors 1160. For instance, the memory 1165 (e.g., one or more non-transitory computer-readable storage mediums, memory devices) can store data 1175 that can be obtained, received, accessed, written, manipulated, created, and/or stored. The data 1175 can include, for instance, vehicle data, simulation data, itinerary data, and/or other data or information described herein. In some implementations, the computing system 1150 can obtain data from one or more memory device(s) that are remote from the computing system 1150.

The memory 1165 can also store computer-readable instructions 1170 that can be executed by the one or more processors 1160. The instructions 1170 can be software written in any suitable programming language or can be implemented in hardware. Additionally, or alternatively, the instructions 1170 can be executed in logically and/or virtually separate threads on processor(s) 1160. For example, the memory 1165 can store instructions 1170 that when executed by the one or more processors 1160 cause the one or more processors 1160 to perform any of the operations and/or functions described herein, including, for example, any of the operations and functions of the devices described herein, and/or other operations and functions.

The computing device(s) 1155 can also include a communication interface 1180 used to communicate with one or more other system(s). The communication interface 1180 can include any circuits, components, software, etc. for communicating via one or more networks (e.g., 1145). In some implementations, the communication interface 1180 can include for example, one or more of a communications controller, receiver, transceiver, transmitter, port, conductors, software and/or hardware for communicating data/information.

The network(s) 1145 can be any type of network or combination of networks that allows for communication between devices. In some embodiments, the network(s) 1145 can include one or more of a local area network, wide area network, the Internet, secure network, cellular network, mesh network, peer-to-peer communication link and/or some combination thereof and can include any number of wired or wireless links. Communication over the network(s) 1145 can be accomplished, for instance, via a network interface using any type of protocol, protection scheme, encoding, format, packaging, etc.

FIG. 11 illustrates one example system 1100 that can be used to implement the present disclosure. Other computing systems can be used as well. Computing tasks discussed herein as being performed at a transportation services system, the simulation computing system, etc. can instead be performed remote from the respective system, or vice versa. Such configurations can be implemented without deviating from the scope of the present disclosure. The use of computer-based systems allows for a great variety of possible configurations, combinations, and divisions of tasks and functionality between and among components. Computer-implemented operations can be performed on a single component or across multiple components. Computer-implemented tasks and/or operations can be performed sequentially or in parallel. Data and instructions can be stored in a single memory device or across multiple memory devices.

While the present subject matter has been described in detail with respect to specific example embodiments and methods thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A computer-implemented method, the method comprising:
obtaining, by a computing system comprising one or more computing devices,
simulation data indicative of a simulated flight itinerary, wherein the simulated flight itinerary is indicative of an expected performance of an aerial transportation service for a multi-modal transportation itinerary;
obtaining, by the computing system, operational data indicative of a performed flight itinerary of the multi-modal transportation itinerary, wherein the performed flight itinerary is indicative of a recorded performance of the aerial transportation service;
determining, by the computing system, one or more performance deviations associated with the simulated flight itinerary based, at least in part, on the simulation data and the operational data;
generating, by the computing system, one or more corrective actions based, at least in part, on the one or more performance deviations, wherein the one or more corrective actions are associated with at least one of a generation of the simulated flight itinerary or a selection of the simulated flight itinerary; and
outputting, by the computing system, the one or more corrective actions.

2. The computer-implemented method of claim 1, wherein determining the one or more performance deviations associated with the simulated flight itinerary based, at least in part, on the simulation data and the operational data comprises:
determining, by the computing system, the one or more performance deviations based, at least in part, on the recorded performance of the aerial transportation service.

3. The computer-implemented method of claim 1, wherein the expected performance of the aerial transportation service comprises a plurality of expected performance parameters, wherein the recorded performance of the aerial transportation service comprises a plurality of recorded performance parameters, and wherein the one or more performance deviations are indicative of one or more differences between the plurality of recorded performance parameters and the plurality of expected performance parameters.

4. The computer-implemented method of claim 3, wherein the simulation data is indicative of a plurality of simulated flight itineraries for one or more operational time periods, wherein the operational data is indicative of a plurality of performed flight itineraries during the one or more operational time periods, and wherein generating the one or more corrective actions comprise:
identifying, by the computing system, a shared performance deviation associated with one or more of the plurality of simulated flight itineraries based, at least in part, on the operational data;
determining, by the computing system, one or more correlating parameters of the one or more simulated flight itineraries associated with the shared performance deviation; and
generating, by the computing system, a corrective action for the shared performance deviation based, at least in part, on the one or more correlating parameters.

5. The computer-implemented method of claim 4, wherein at least one of the one or more correlating parameters are indicative of an aerial vehicle provider associated with each of the one or more simulated flight itineraries, and wherein the corrective action for the shared performance deviation comprises associating the shared performance deviation with the aerial vehicle provider.

6. The computer-implemented method of claim 5, wherein each respective simulated flight itinerary of the plurality of simulated flight itineraries is generated before the performance of a corresponding aerial transportation service at a respective time step of a respective operational time period based, at least in part, on one or more operational constraints for the respective time step, and
wherein a respective performed flight itinerary of the plurality of performed flight itineraries corresponds to the corresponding aerial transportation service at the respective time step of the respective operational time period.

7. The computer-implemented method of claim 6, wherein the one or more correlating parameters comprise one or more operational constraints associated with each of the one or more simulated flight itineraries, wherein the one or more operational constraints comprise at least one of one or more demand constraints, multi-modal itinerary constraints, vehicle constraints, or environmental constraints.

8. The computer-implemented method of claim 7, wherein the corrective action for the shared performance deviation is indicative of a modification to a determination of at least one of the one or more operational constraints.

9. The computer-implemented method of claim 8, wherein the at least one of the one or more operational constraints is a vehicle constraint determined based, at least in part, on a vehicle model indicative of a plurality of vehicle attributes of a vehicle associated with the one or more simulated flight itineraries, and wherein the modification to the determination of the vehicle constraint comprises a change to at least one of the plurality of vehicle attributes.

10. The computer-implemented method of claim 1, wherein outputting the one or more corrective actions comprises:
providing for display, by the computing system via one or more display devices, data indicative of the one or more corrective actions, the data indicative of the one or more corrective actions indicative of at least one modification to the generation of the simulated flight itinerary or the selection of the simulated flight itinerary and a predicted impact of the at least one modification.

11. One or more tangible, non-transitory computer-readable media storing computer-readable instructions that when executed by one or more processors cause the one or more processors to perform operations, the operations comprising:
obtaining simulation data indicative of a simulated flight itinerary, wherein the simulated flight itinerary is indicative of an expected performance of an aerial transportation service for a multi-modal transportation itinerary;
obtaining operational data indicative of a performed flight itinerary of the multi-modal transportation itinerary, wherein the performed flight itinerary is indicative of a recorded performance of the aerial transportation service;
determining one or more performance deviations associated with the simulated flight itinerary based, at least in part, on the simulation data and the operational data;
generating one or more corrective actions based, at least in part, on the one or more performance deviations, wherein the one or more corrective actions are associated with a selection of the simulated flight itinerary; and
outputting the one or more corrective actions.

12. The one or more tangible, non-transitory computer-readable media of claim 11, wherein the simulation data is indicative of a plurality of simulated flight itineraries, each respective simulated flight itinerary generated before a performance of a corresponding aerial transportation service at a respective time step of an operational time period.

13. The one or more tangible, non-transitory computer-readable media of claim 12, wherein the plurality of simulated flight itineraries comprise one or more selected itineraries, one or more provided itineraries, and one or more discarded itineraries, wherein the operational data is indicative of a plurality of performed flight itineraries comprising a respective performed flight itinerary for each of the one or more selected itineraries.

14. The one or more tangible, non-transitory computer-readable media of claim 13, wherein the one or more provided itineraries comprise a plurality of ranked lists of simulated flight itineraries for one or more time steps throughout one or more operational time periods, wherein each ranked list of simulated flight itineraries is ranked according to one or more cost functions.

15. The one or more tangible, non-transitory computer-readable media of claim 14, wherein each respective selected itinerary of the one or more selected itineraries are selected from a respective ranked list of simulated flight itineraries.

16. The one or more tangible, non-transitory computer-readable media of claim 14, wherein the corrective action comprises a modification to at least one of the one or more cost functions.

17. The one or more tangible, non-transitory computer-readable media of claim 14, wherein each respective ranked list of simulated flight itineraries comprises contextual data for each respective simulated flight itinerary of the respective ranked list.

18. The one or more tangible, non-transitory computer-readable media of claim 17, wherein the contextual data is determined for each respective simulated flight itinerary based, at least in part, on one or more selection criteria, and wherein the corrective action comprises a modification to the one or more selection criteria.

19. The one or more tangible, non-transitory computer-readable media of claim 11, wherein generating the one or more corrective actions based, at least in part, on the one or more performance deviations comprises:
obtaining feedback data associated with the selection of the simulated flight itinerary, wherein the feedback data comprises user input or metadata associated with the user input; and
generating the one or more corrective actions based, at least in part, on the feedback data.

20. A computing system comprising:
one or more processors; and
one or more tangible, non-transitory, computer readable media that collectively store instructions that when executed by the one or more processors cause the computing system to perform operations, the operations comprising:
obtaining simulation data indicative of a simulated flight itinerary, wherein the simulated flight itinerary is indicative of an expected performance of an aerial transportation service;
obtaining operational data indicative of a performed flight itinerary, wherein the performed flight itinerary is indicative of a recorded performance of the aerial transportation service;
determining one or more performance deviations associated with the simulated flight itinerary based, at least in part, on the recorded performance of the aerial transportation service;
generating one or more corrective actions based, at least in part, on the one or more performance deviations, wherein the one or more corrective actions are associated with at least one of a generation of the simulated flight itinerary or a selection of the simulated flight itinerary; and
providing the one or more corrective actions.
